(19) United States
(12) Patent Application Publication
(10) Pub. No.: US 2026/0314309 A1
(43) Pub. Date: Oct. 8, 2026

(54) MAPPING DEVICE AND MAPPING METHOD

(71) Applicant: Sinfonia Technology Co., Ltd., Tokyo (JP)

(72) Inventors: Tatsuru Ogawa, Tokyo (JP); Yuki Ishihara, Tokyo (JP); Shinpei Kogiso, Tokyo (JP)

(73) Assignee: Sinfonia Technology Co., Ltd., Tokyo (JP)

(21) Appl. No.: 19/482,331

(22) PCT Filed: Apr. 24, 2024
(86) PCT No.: PCT/JP2024/016000

§ 371 Date: Nov. 7, 2025

(30) Foreign Application Priority Data
May 9, 2023 (JP) 2023-077283

(51) Int. Cl. H10P 72/00; H10P 72/10

(52) U.S. Cl. CPC H10P 72/0608; H10P 72/10

(57) ABSTRACT

A mapping device includes: a first mapping sensor that is arranged on one side in an extension direction of an end surface of a rectangular substrate accommodated in an accommodation container, and while moving in an arrangement direction of the substrate, outputting an on signal upon detecting the end surface at a first detection point; a second mapping sensor arranged on the other side in the extension direction of the end surface, and while moving in the arrangement direction, outputting an on signal upon detecting an end surface at a second detection point located on the downstream side of the first detection point in a direction of the movement; and a mapping processor determining an accommodation state of the substrates based on a first input signal input from the first mapping sensor and a second input signal input from the second mapping sensor via an off-delay timer displaying an off signal.

### TECHNICAL FIELD

The present disclosure relates to a mapping device and a mapping method.

### BACKGROUND

A highly clean environment (clean environment) is required in processes of manufacturing semiconductors and liquid crystals. In recent years, a mini-environment system has been increasingly adopted instead of a downflow system to create a clean environment in factories for manufacturing semiconductors or liquid crystals. The mini-environment system is a system that creates a localized clean environment only around a substrate, which is a workpiece, and can create a highly clean environment at a lower cost than a downflow system which creates a clean environment throughout the entire factory.

In the mini-environment system, a substrate is transferred and stored with being accommodated in an accommodation container that is kept at a higher cleanliness than the outside atmosphere. In order to transfer the substrate between the accommodation container and a processing apparatus that performs various processes on the substrate, a module called an equipment front end module (EFEM) is used. The EFEM includes a transfer part including a transfer chamber and a transfer robot installed therein, and a load port connected to the transfer part. The load port is an interface for loading and unloading the substrate between the accommodation container that accommodates the substrate and the transfer part. The substrate accommodated in the accommodation container is delivered between the accommodation container and the transfer part (and hence the processing apparatus) via the load port without being exposed to the outside atmosphere (see, e.g., Patent Documents 1 and 2).

### PRIOR ART DOCUMENTS

### Patent Documents

Patent Document 1: Japanese laid-open publication No. 2021-128995

Patent Document 2: Japanese laid-open publication No. 2023-23465

Patent Document 3: Japanese laid-open publication No. 2021-19124

The accommodation container includes, for example, a container body provided with an opening on one side thereof and a lid configured to close the opening. The container body has a plurality of shelves for supporting a plurality of substrates, each of which supports one substrate, thereby storing the substrates in multiple stages in the container body.

As illustrated in FIGS. 17A to 17C, each shelf provided in the container body includes, for example, a plurality of (e.g., three) support rods 931 provided at the same height. Each support rod 931 is provided, for example, so as to protrude from an inside of the container body toward the opening. When all of the support rods 931 constituting one shelf 93 support the same substrate W, the substrate W is supported in a horizontal posture (FIG. 17A). However, the substrate W is not always supported normally. For example, there may occur a state in which only some of the support rods 931 constituting one shelf 93 support the substrate W, while the rest do not support the substrate W (FIG. 17B). Such a state is also called a cross abnormality state. A state in which a substrate W is supported across multiple shelves 93 is also one form of the cross abnormality state. In a case where the substrate W is in the cross abnormality state, there is a risk that a hand of a transfer robot will collide with the substrate W. Therefore, when the substrate W is in the cross abnormality state, it is necessary to detect such a state.

For example, in order to detect a cross abnormality state, sensors 900a and 900b may be provided on one side and the other side of an end surface of the substrate W in an extension direction thereof to detect the end surface from positions opposite the end surface. These two sensors 900a and 900b are held at the same height and moved in an arrangement direction of the substrates W (e.g., downward), causing the respective sensors 900a and 900b to detect the end surface of the substrate W. Then, for example, when the substrate W is normally supported and the end surface is disposed at approximately the same height throughout its entire extension direction (FIG. 17A), the respective sensors 900a and 900b detect the end surface of the substrate W at approximately the same timing. On the other hand, when the substrate W is in a cross abnormality state and the end surface is sagging obliquely at one end in the extension direction thereof (e.g., FIG. 17B), the timings at which the respective sensors 900a and 900b detect the end surface will differ. Therefore, in a case where the pair of sensors 900a and 900b detect the end surface at different timings, it can be determined that the substrate W is in a cross abnormality state.

However, in recent years, as substrates W have become thinner and larger, the substrates W supported on the shelves 93 may be warped or distorted (see, for example, FIG. 17C). In this case, even in a case where the substrate W is supported normally (i.e., even in a case where all of the multiple support rods 931 constituting one shelf 93 support the same substrate W), the timings at which the sensors 900a and 900b detect the end surface may differ. Therefore, a normally supported substrate W may be erroneously determined to be in a cross abnormality state.

The present disclosure was made to solve the above-mentioned problems. It is an object of the present disclosure to provide a technique capable of determining an accommodation state of a substrate with sufficient accuracy.

### SUMMARY

In order to achieve the above object, the present disclosure takes the following measures.

The present disclosure provides a mapping device, which includes: a first mapping sensor arranged on one side of an end surface of a rectangular substrate accommodated in an accommodation container in an extension direction of the end surface and configured to move in an arrangement direction of the substrate and output an on signal upon detecting the end surface at a first detection point; a second mapping sensor arranged on the other side of the end surface in the extension direction of the end surface and configured to move in the arrangement direction of the substrate and output an on signal upon detecting the end surface at a second detection point on a downstream side of the first detection point in a direction of the movement of the second mapping sensor; and a mapping processor configured to determine an accommodation state of the substrate based on a first input signal input from the first mapping sensor and a second input signal input from the second mapping sensor via an off-delay timer configured to delay an off signal.

According to this configuration, an offset width between the first detection point and the second detection point in the direction of the movement, and a delay time set for the off signal of the second mapping sensor are adjusted so that a relationship between timings at which the first input signal and the second input signal are switched on and off varies depending on the accommodation state to be determined, thereby, making it possible to determine the accommodation state of the substrate with sufficient accuracy based on the relationship between the timings.

Preferably, in the mapping device, the mapping processor determines that the substrate is not supported normally when the second input signal is the off signal at both of rising and falling times of the first input signal.

According to this configuration, the accommodation status of the substrate can be determined quickly while reducing a processing load.

Preferably, in the mapping device, the first input signal is a signal input from the first mapping sensor to the mapping processor via an off-delay timer configured to delay an off signal, and a delay time set for the off signal output from the first mapping sensor is shorter than a delay time set for the off signal output from the second mapping sensor.

According to this configuration, since the first input signal input to the mapping processor is the off signal output from the first mapping sensor with a relatively short first delay time set. Therefore, even in a case where chattering occurs in the signal output from the first mapping sensor, an influence of the chattering is reduced or eliminated. Accordingly, the accuracy of determining the accommodation state is less likely to be reduced.

Preferably, in the mapping device, an optical axis of the second mapping sensor is inclined in the direction of the movement with respect to an optical axis of the first mapping sensor.

According to this configuration, the offset width between the first detection point and the second detection point in the direction of the movement can be adjusted by adjusting an angle between the optical axis of the first mapping sensor and the optical axis of the second mapping sensor.

In another aspect, the present disclosure provides a mapping method, which includes: a detection step of causing a first mapping sensor, which is arranged on one side of an end surface of a rectangular substrate accommodated in an accommodation container in an extension direction of the end surface and configured to output an on signal upon detecting the end surface at a first detection point and a second mapping sensor, which is arranged on the other side of the end surface in the extension direction and configured to output an on signal upon detecting the end surface at a second detection point, to move in an arrangement direction of the substrate and detect the end surface; and a mapping processing step of determining an accommodation state of the substrate based on a first input signal input from the first mapping sensor and a second input signal input from the second mapping sensor, wherein the second detection point is located on a downstream side of the first detection point in a direction of the movement, and the second input signal is a signal input from the second mapping sensor via an off-delay timer configured to delay an off signal.

According to this configuration, an offset width between the first detection point and the second detection point in the direction of the movement, and a delay time set for the off signal of the second mapping sensor are adjusted so that a relationship between timings at which the first input signal and the second input signal are switched on and off varies depending on the accommodation state to be determined, thereby making it possible to determine the accommodation state of the substrate with sufficient accuracy based on the relationship between the timings.

According to the present disclosure, it is possible to determine an accommodation state of a substrate with sufficient accuracy.

### BRIEF DESCRIPTION OF DRAWINGS

FIGS. 1A and 1B are a side cross-sectional view and a top cross-sectional view of an accommodation container.

FIG. 2 is a perspective view of an EFFM including a load port according to an embodiment.

FIG. 3 is a side view showing a schematic configuration of an EFFM.

FIG. 4 is a perspective view of a load port as viewed obliquely from above on a front side thereof.

FIG. 5 is a side cross-sectional view of a load port.

FIG. 6 is a diagram showing an operation flow of a load port.

FIGS. 7A to 7D are diagrams for explaining an operation of a load port.

FIG. 8 is a side cross-sectional view showing the vicinity of an opening portion.

FIG. 9 is a top cross-sectional view showing the vicinity of an opening portion.

FIG. 10 is a block diagram showing a configuration of a mapping part.

FIGS. 11A to 11C are diagrams for explaining a first input signal.

FIGS. 12A and 12B are diagrams for explaining a relationship between a posture of an accommodated substrate and a timing at which an input signal is switched.

FIGS. 13A to 13C are diagrams for explaining the relationship between a posture of an accommodated substrate and a timing at which an input signal is switched.

FIGS. 14A to 14C are diagrams for explaining a relationship between a posture of an accommodated substrate and a timing at which an input signal is switched.

FIGS. 15A to 15C are diagrams for explaining movement of a mapping sensor.

FIG. 16 is a diagram showing a flow of a mapping process.

FIGS. 17A to 17C are diagrams schematically illustrating an accommodated states of a

### DETAILED DESCRIPTION

Hereinafter, an embodiment of the present disclosure will be described with reference to the drawings.

### 1. Schematic Configuration of Accommodation Container

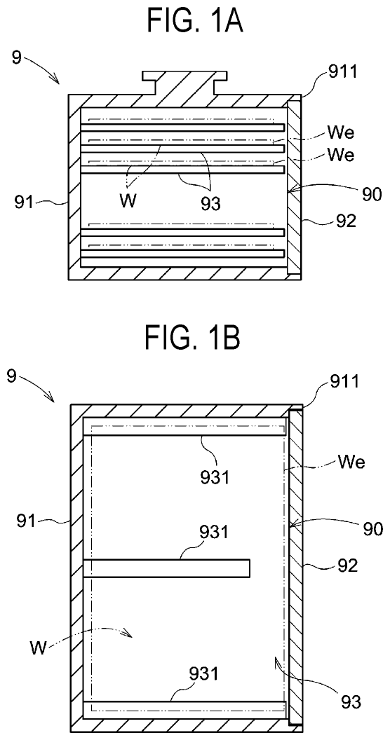

First, a schematic configuration of an accommodation container 9 in which substrates W are accommodated will be described with reference to FIGS. 1A and 1B. FIGS. 1A and 1B are a side cross-sectional view and a top cross-sectional view of the accommodation container 9.

The accommodation container 9 is a container configured to contain a plurality of substrates W. Here, the accommodation container 9 contains rectangular (square) substrates W. The substrates W contained therein may be relatively large or relatively thin. For example, a plan-view size of the substrate W may be 600 mm×600 mm, 515 mm×510 mm, 300 mm×300 mm, 241 mm×241 mm, or the like. A thickness of the substrate W may be 0.1 mm to 3.2 mm. Material of the substrate W may be any material. For example, the material of the substrate W may be glass (so-called glass substrate) or glass epoxy (so-called glass epoxy substrate). Alternatively, the material of the substrate W may be copper (copper plate), resin, stainless steel (stainless steel plate), or the like.

The accommodation container 9 is, for example, a sealed container, and includes a container body 91 having an opening 90 on one side surface thereof, and a lid 92 configured to close the opening 90 of the container body 91. Such an accommodation container 9 is also called a front opening unified pod (FOUP), etc. The container body 91 is provided with a jaw portion 911 that surrounds the opening 90, and the lid 92 is installed inside the jaw portion 911. In a state in which the lid 92 is installed, the jaw portion 911 abuts against the periphery of the lid 92, thereby sealing the inside of the container body 91. The lid 92 is provided with a latch (not shown) configured to fix the lid 92 to the container body 91.

A plurality of shelves 93 configured to support the substrates W are provided inside the container body 91. The shelves 93 are provided at equal intervals along an up-down direction, and each shelf 93 supports one substrate W. That is, each shelf 93 forms a slot configured to accommodate one substrate W. Each shelf 93 includes, for example, three support rods 931 provided at the same height. Two of the three support rods 931 are provided near side walls of the container body 91, and the remaining support rod 931 is provided between these two support rods 931. Each support rod 931 is provided so as to protrude from an inside of the container body 91 toward the opening 90. The three support rods 931 constituting one shelf 93 support one substrate W in a posture in which a thickness direction thereof extends along the up-down direction and one end surface We extends in parallel to the opening 90 when viewed from above. The substrates W are supported on the plurality of shelves 93 provided in the container body 91, respectively, such that the plurality of substrates W are accommodated in multiple stages in the container body 91.

### 2. Schematic Configuration of EFFM

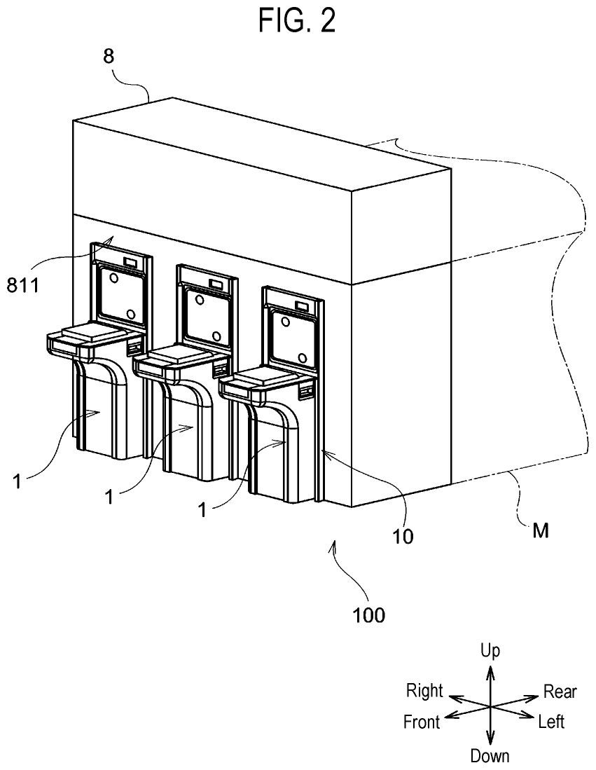

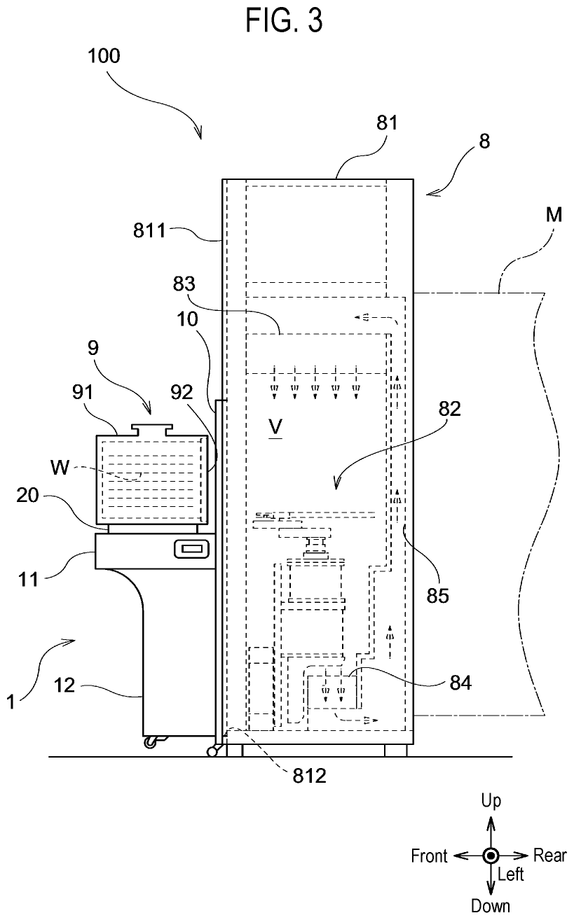

Next, a schematic configuration of an equipment front end module (EFFM) including a load port according to an embodiment will be described with reference to FIGS. 2 and 3. FIG. 2 is a perspective view of the EFFM 100. FIG. 3 is a side view showing the schematic configuration of the EFFM 100.

The EFFM 100 is used in a process of manufacturing semiconductors or liquid crystals. The EFFM 100 is a module configured by combining a load port 1 and a transfer part 8, and has a configuration in which, for example, a plurality of load ports 1 (three load ports in the illustrated example) arranged in a row are connected to one end of the transfer part 8. The EFEM 100 is connected to a processing apparatus M configured to perform various processes on the substrate W, at an end of the transfer part 8 opposite to an end where the load port 1 is provided, and is configured to deliver the substrate W between the processing apparatus M and an accommodation container 9. In the following, the side of the transfer part 8 on which the load port 1 is provided is referred to as a “front side,” and the side of the transfer part 8 on which the processing apparatus M is provided is referred to as a “rear side.” A horizontal direction orthogonal to a front-rear direction (i.e., an arrangement direction of the plurality of load ports 1) is referred to as a “left-right direction.”

The load port 1 is a device configured to bring the inside of the accommodation container 9 configured to accommodate the substrates W into communication with the inside of the transfer part 8 without exposing the inside to the outside atmosphere. Specifically, the load port 1 removes the lid 92 of the accommodation container 9 from the container body 91 to bring the inside of the container body 91 into communication with a transfer space V, which is an internal space of the transfer part 8. When the inside of the container body 91 is in communication with the transfer space V, the transfer robot 82 arranged in the transfer space V takes out the substrate W (e.g., an unprocessed substrate W) accommodated in the container body 91 from the container body 91 and transfers the same into the processing apparatus M. In addition, for example, the transfer robot 82 takes out the substrate W that has been subjected to a predetermined process in the processing apparatus M from the processing apparatus M and stores the same in the container body 91. When a predetermined number of substrates W are stored in the container body 91, the load port 1 attaches the lid 92 to the container body 91 to seal the accommodation container 9 again. A specific configuration of the load port 1 will be described later.

The transfer part 8 is a device configured to transfer the substrate W accommodated in the accommodation container 9, and includes a transfer chamber 81 and a transfer robot 82 arranged therein. One or more openings 812 (three openings in the illustrated example) are formed in a front wall portion 811 of the transfer chamber 81, and the load ports 1 are airtightly attached so as to close the respective openings 812. In addition, the processing apparatus M (e.g., a load lock chamber of the processing apparatus M) is airtightly connected to a rear wall portion of the transfer chamber 81 via, for example, a gate valve. Thus, the internal space (transfer space) V of the transfer chamber 81 becomes a substantially-sealed space.

The transfer space V is maintained at a higher cleanliness than the outside (i.e., a clean room in which the processing apparatus M is installed). Specifically, for example, a fan filter unit (FFU) 83 is installed in the transfer chamber 81, and a gas purified by the fan filter unit 83 is sent downward to form a downflow of clean gas in the transfer space V. Preferably, a chemical filter 84, a circulation duct 85, and the like are further installed in the transfer space V. The gas flow that reaches a lower part of the transfer space V passes through the chemical filter 84 where contaminants and the like are removed. Then, the gas flow is returned to the fan filter unit 83 via the circulation duct 85 and is sent downward again (i.e., gas circulation is formed).

In addition, the transfer chamber 81 is provided with a gas supply port and a gas exhaust port (both not shown), and is configured such that a predetermined gas (e.g., nitrogen gas, dry air, dry nitrogen gas, etc.) can be purged via the gas supply port, and the gas in the transfer space V can be discharged via the gas exhaust port. By controlling an amount of gas supplied via the gas supply port and an amount of gas exhausted via the gas exhaust port, a pressure, a gas concentration, and the like in the transfer space V can be adjusted to arbitrary values. Here, the amount of gas supplied and the amount of gas exhausted are appropriately controlled, such that the transfer space V is maintained at a pressure (slightly positive pressure) slightly higher than the outside (i.e., the clean room in which the processing apparatus M is installed). This ensures that even in a case where there is a small gap that brings the inside and outside of the transfer chamber 81 into communication with each other, a gas does not flow into the transfer space V from the outside via the gap.

### 3. Configuration of Load Port

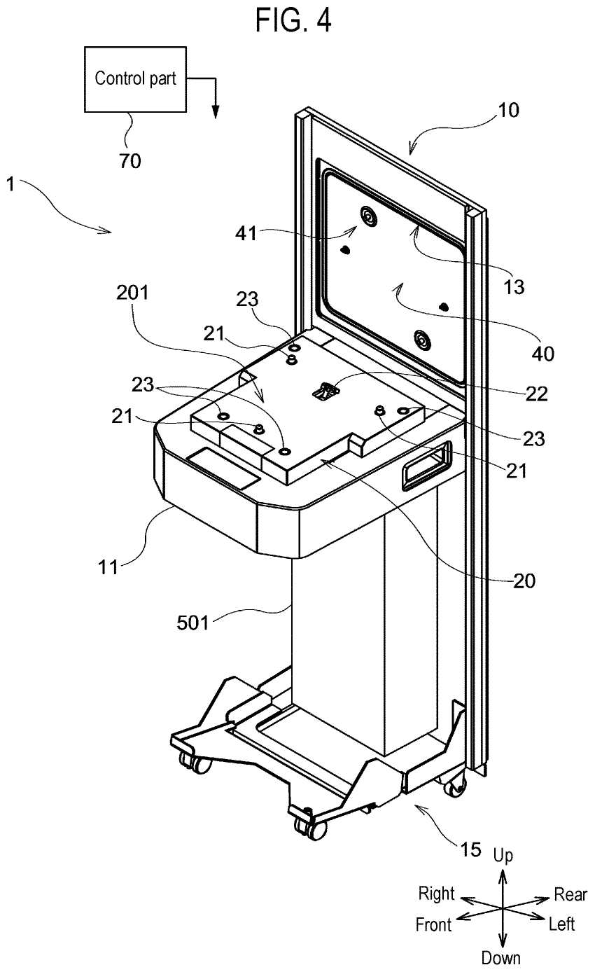

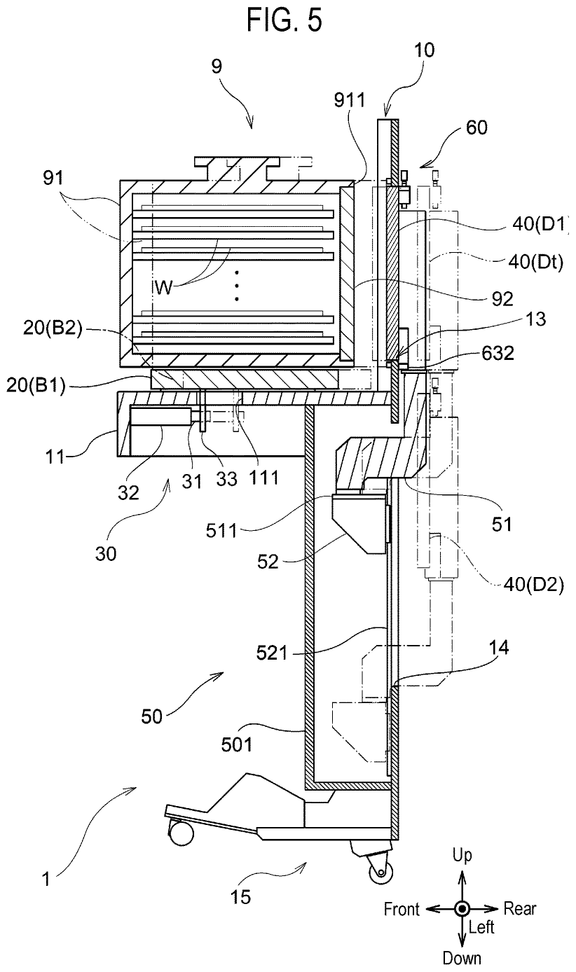

A configuration of the load port 1 will be specifically described with reference to FIGS. 2, 3, 4 and 5. FIG. 4 is a perspective view of the load port 1 as viewed obliquely from above on a front side thereof. FIG. 5 is a side cross-sectional view of the load port 1.

The load port 1 includes a base part 10, a mounting part 20, a mounting part drive mechanism 30, a door part 40, a door part drive mechanism 50, and a mapping part 60. The load port 1 also includes a control part 70 that controls the respective parts.

### (Base Part 10)

The base part 10 is a plate-like member that constitutes a portion of the front wall portion of the transfer part 8 (FIG. 2). Specifically, the base part 10 is a flat plate-like member (panel member) that is larger than the opening 812 (FIG. 3) formed in the front wall portion 811 of the transfer chamber 81, and is attached to the wall portion 811 in an upright posture so as to close the opening 812. The base part 10 constitutes the front wall portion of the transfer part 8 together with the wall portion 811. For example, a gasket is provided on a rear surface of the base part 10. The base part 10 is attached airtightly to the wall portion 811 via the gasket.

A base stand 11 protruding forward in a substantially horizontal posture is provided on a front surface of the base part 10. A cover 12 (FIG. 3) is provided below the base stand 11 (for convenience of explanation, a state in which the cover 12 is removed is illustrated in FIGS. 4 and 5). An opening portion 13 is provided in the surface of the base part 10 to allow the substrate W to pass therethrough. The opening portion 13 is formed at a position facing the lid 92 of the container 9 mounted on the mounting part 20 provided on the base stand 11. A size of the opening portion 13 is slightly larger than the lid 92 of the accommodation container 9, and the lid 92 is configured to be able to pass through the opening portion 13. In addition, a slit 14 extending in the up-down direction is provided in the surface of the base part 10 below the opening portion 13 so as to allow a below-described support frame 51 to pass therethrough. Furthermore, legs 15 including casters or the like are provided on the front surface of the base part 10 so as to protrude forward. The legs 15 come into contact with a floor surface to support the base part 10.

### (Mounting Part 20)

The mounting part 20 is a flat plate-shaped member, and is arranged in a horizontal posture on the base stand 11 that protrudes forward from the base part 10. The accommodation container 9 is mounted on the mounting part 20. That is, an upper surface of the mounting part 20 forms a mounting surface 201 on which the accommodation container 9 is mounted. The accommodation container 9 is mounted on the mounting surface 201 with the lid 92 facing the base part 10.

The mounting surface 201 is provided with positioning pins (guide pins) 21 configured to engage with recesses provided on a bottom surface of the accommodation container 9 to guide and position the accommodation container 9 at a predetermined position. The mounting surface 201 is also provided with a locking portion 22 configured to be hooked onto a fixing portion (e.g., a front retaining feature) provided on the bottom surface of the accommodation container 9 to fix the accommodation container 9 at the predetermined position.

In addition, one or more gas nozzles 23 are provided on the mounting surface 201. Each gas nozzle 23 may be used as a gas supply nozzle configured to supply a predetermined gas (e.g., nitrogen gas, inert gas, dry air, etc.) into the accommodation container 9 via a gas supply valve provided on the bottom surface of the accommodation container 9, or may be used as a gas exhaust nozzle configured to exhaust a gas from the accommodation container 9 via a gas exhaust valve provided on the bottom surface of the accommodation container 9. For example, when the gas nozzles 23 are provided at four corners of the mounting surface 201, a pair of gas nozzles 23 on the front side may be used as gas supply nozzles, and a pair of gas nozzles 23 on the rear side may be used as gas exhaust nozzles. Each gas nozzle 23 is arranged below the mounting surface 201 when not in use, and is moved upward and connected to the gas supply valve or gas exhaust valve of the accommodation container 9 when in use. A predetermined gas (e.g., nitrogen gas, dry air, dry nitrogen gas, etc.) is purged into the accommodation container 9 from the gas nozzle 23 as a gas supply nozzle via a gas supply valve, and the gas in the accommodation container 9 is discharged from the gas nozzle 23 as a gas discharge nozzle via a gas discharge valve, such that the inside of the accommodation container 9 can be replaced with the predetermined gas. In addition, a pressure in the accommodation container 9 can be adjusted to an arbitrary value by controlling a gas supply amount and a gas discharge amount. Preferably, the gas supply amount and the gas discharge amount are appropriately controlled such that the inside of the accommodation container 9 is kept at a pressure slightly higher than the outside (e.g., the clean room in which the processing apparatus M is installed and the transfer space V of the transfer part 8). This makes it difficult for a gas to flow into the inside of the container body 91 when the lid 92 of the accommodation container 9 is opened.

### (Mounting Part Drive Mechanism 30)

The mounting part drive mechanism 30 moves the mounting part 20 in a direction (front-rear direction) toward and away from the base part 10 while keeping the mounting part 20 in a horizontal posture, thereby moving the mounting part 20 between a separation position B1 (position shown by a solid line in FIG. 5) and a dock position B2 (position shown by a two-dot chain line in FIG. 5). Here, the “separation position B1” is a position where the mounting part 20 is separated from the base part 10 by a predetermined distance, and is a position where an external robot such as an AMHS, a PGV, or an OHT delivers the accommodation container 9 to the mounting part 20. On the other hand, the “dock position B2” is a position closer to the base part 10 than the separation position B1, and specifically, for example, a position where the jaw portion 911 of the accommodation container 9 mounted on the mounting part 20 abuts against the front surface of the base part 10.

Specifically, the mounting part drive mechanism 30 includes, for example, a rod (cylinder rod) 31 that is provided in a posture extending forward and rearward in a horizontal plane, a cylinder (air cylinder) 32 as a drive part configured to move the rod 31 forward and rearward along an extension direction of the rod 31, and a connection part 33 configured to connect the rod 31 and the mounting part 20. For example, the air cylinder 32 controls the air pressure by opening and closing a solenoid valve to move the rod 31 forward and rearward with the air pressure. The rod 31 and the air cylinder 32 are arranged in the base stand 11. On the other hand, the connection part 33 is installed to pass through a slit 111 which is provided on an upper surface of the base stand 11 to extend forward and rearward. The connection part 33 is connected to the rod 31 at a lower end that protrudes downward from the base stand 11, and is connected to the lower surface of the mounting part 20 at an upper end that protrudes upward from the base stand 11. In this configuration, when the rod 31 is driven by the air cylinder 32 to move back and forth, the mounting part 20 connected to the rod 31 via the connection part 33 is guided by a linear guide (not shown) provided on the base stand 11 to move back and forth in the horizontal plane.

### (Door Part 40)

The door part 40 is a member configured to open and close the opening portion 13 formed in the base part 10, and is provided on a rear surface side of the base part 10 (i.e., the side opposite the mounting part 20 across the base part 10). The door part 40 is made of a flat plate-shaped member that has approximately the same size as the opening portion 13 (or is larger than the opening portion 13). When arranged at a closed position D1 (position indicated by a solid line in FIG. 5), the door part 40 entirely closes the opening portion 13. At this time, the door part 40 abuts against (or comes into close contact via a sealing member or the like) a peripheral edge of the opening portion 13, thereby sealing the transfer space V. On the other hand, when the door part 40 is arranged at an open position D2 (position indicated by the one-dot chain line in FIG. 5) described later, the entire opening portion 13 is opened.

The door part 40 is provided with a lid holding mechanism 41. When the door part 40 is closing the opening portion 13, the lid holding mechanism 41 integrally connects the lid 92 arranged opposite the opening portion 13 to the door part 40, thereby holding the lid 92 on the door part 40. The lid holding mechanism 41 also performs latching and unlatching between the container body 91 and the lid 92.

### (Door Part Drive Mechanism 50)

The door part drive mechanism 50 moves the door part 40 between a closed position D1 and an open position D2. Here, the “closed position D1” is a position where the door part 40 entirely closes the opening portion 13. On the other hand, the “open position D2” is a position where the door part 40 entirely opens the opening portion 13, specifically, a position where the door part 40 retracts to a location below the opening portion 13 and does not completely overlap with the opening portion 13.

Specifically, the door part drive mechanism 50 includes, for example, a support frame 51 configured to support the door part 40, and a lifting block 52 configured to support the support frame 51. The support frame 51 is connected at one end to the door part 40 (e.g., the lower portion of the rear surface of the door part 40), extends downward from the one end, bends forward halfway, extends substantially horizontally, and passes through the slit 14 provided in the base part 10. The other end of the support frame 51 is connected to the lifting block 52 in front of the base part 10. A slide support part 511 configured to support the support frame 51 so as to be movable back and forth is provided between the support frame 51 and the lifting block 52. The support frame 51 is supported so as to be movable back and forth with respect to the lifting block 52. In addition, a slide rail 521 configured to support the lifting block 52 so as to be movable up and down is provided between the lifting block 52 and the base part 10. The lifting block 52 is supported so as to be movable up and down with respect to the base part 10.

The door part drive mechanism 50 further includes a drive source (e.g., a stepping motor as a drive source), a linear motion mechanism configured to convert the power delivered from the drive source into a lifting/lowering motion of the lifting block 52, a linear motion mechanism configured to convert the power into a forward/rearward movement motion of the support frame 51, a link mechanism configured to link these two linear motion mechanisms, and the like (all of which are not shown). Each linear motion mechanism may be configured to include, for example, a feed screw. For example, when moving the door part 40 from the closed position D1 to the open position D2, the power from the drive source is transmitted to the linear motion mechanism on the side of the support frame 51, and then transmitted to the linear motion mechanism on the side of the lifting block 52 via the link mechanism. As a result, the door part 40 located at the closed position D1 is moved rearward, and is first arranged at a motion conversion position Dt (position indicated by the two-dot chain line in FIG. 5) and then moved downward from there to the open position D2. On the other hand, when moving the door part 40 from the open position D2 to the closed position D1, the power from the drive source is transmitted to the linear motion mechanism on the side of the lifting block 52, and then transmitted to the linear motion mechanism on the side of the support frame 51 via the link mechanism. As a result, the door part 40 located at the open position D2 is moved upward, and is first arranged at the motion conversion position Dt and then moved forward from there to the closed position D1.

In addition, a housing 501 is provided on the front surface of the base part 10 and connected to the base part 10 in an airtight manner. Among elements of the door part drive mechanism 50, those arranged on the front surface side of the base part 10 are accommodated in the housing 501. This prevents a gas that flows into the housing 501 through the slit 14 from flowing out to the outside of the housing 501. In addition, among the elements of the door part drive mechanism 50, the slide support part 511 and the slide rail 521 having sliding portions are provided on the front surface side of the base part 10 (i.e., outside the transfer space V) and accommodated in the housing 501. Since a communicating portion between the housing 501 and the transfer space V is formed by the thin slit 14, particles and the like generated at the sliding portions are suppressed from entering the transfer space V.

### (Mapping Part 60)

The mapping part 60 determines (maps) the accommodation state of the substrates W accommodated in the container body 91 of the accommodation container 9 mounted on the mounting part 20. The mapping part 60 will be described later.

### (Control Part 70)

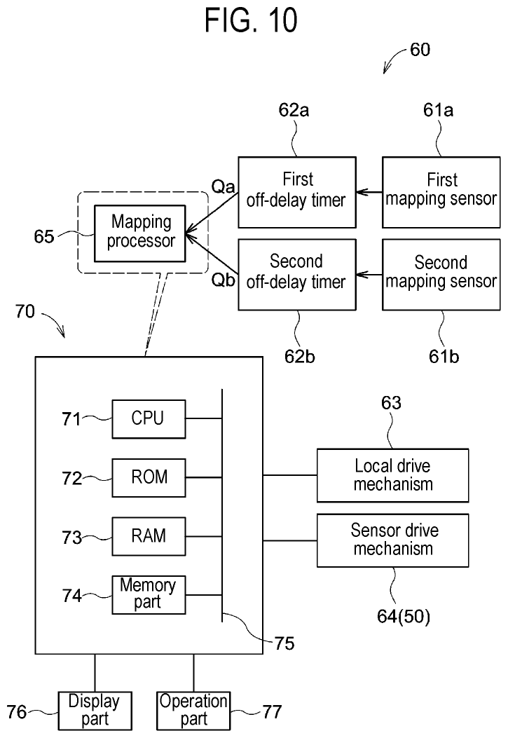

The control part 70 is an element configured to control an operation of each part of the load port 1 and perform various calculation processes, and is constituted by, for example, a general computer with electric circuits, a microcomputer, or the like. Specifically, for example, as shown in FIG. 10, the control part 70 includes a processor such as a central processor unit (CPU) 71 as a central processing device responsible for data processing, a read only memory (ROM) 72 in which basic programs and the like are stored, a random access memory (RAM) 73 used as a working area when the CPU 71 performs predetermined processing (data processing), a memory part 74 constituted by a non-volatile memory device such as a flash memory, a hard disk device or the like, and a bus line 75 configured to connect these components together. In addition, a display part 76 configured to display various kinds of information, an operation part 77 configured to receive various inputs from an operator, and the like are connected to the control part 70.

### 4. Overview of Operation of Load Port

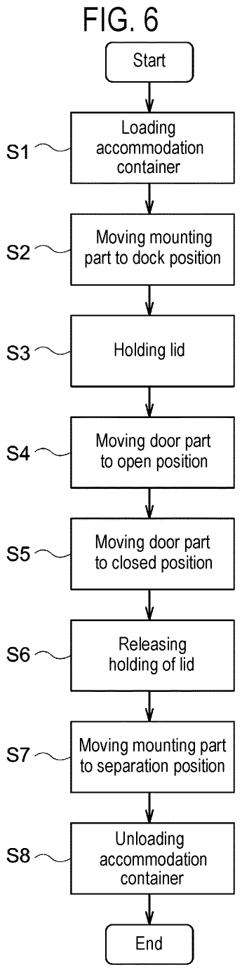

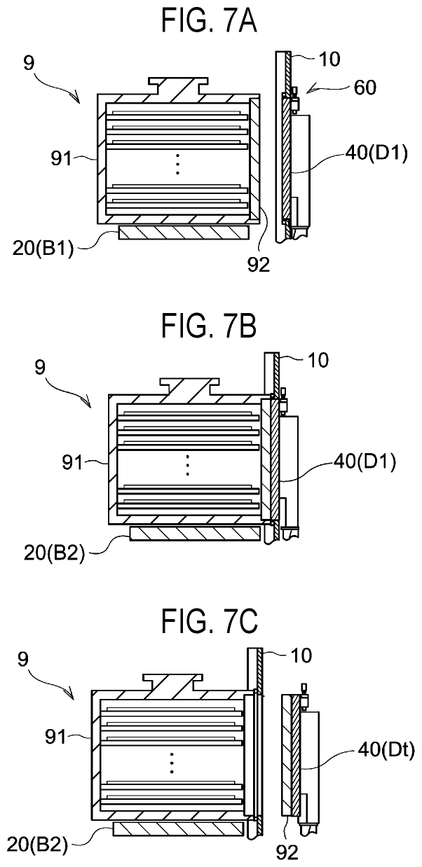

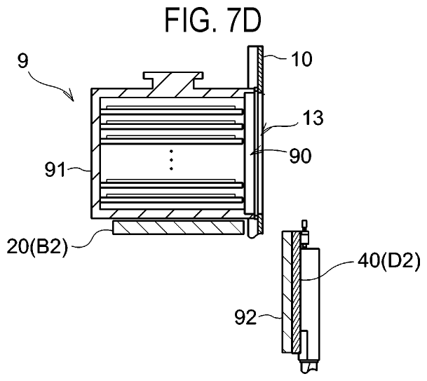

An overview of an operation of the load port 1 will be described with reference to FIGS. 6 and 7A to 7D. FIG. 6 shows an operation flow of the load port 1. FIGS. 7A to 7D are diagrams illustrating the overview of the operation of the load port 1.

A series of operations described below are performed by the control part 70, which controls the respective parts of the load port 1 (specifically, the locking portion 22 and the gas nozzle 23 provided on the mounting part 20, the mounting part drive mechanism 30, the lid holding mechanism 41 provided on the door part 40, the door part drive mechanism 50, the mapping part 60, etc.). The load port 1 is provided with various sensors (mapping sensors 61a and 61b provided in the mapping part 60, a sensor configured to detect that the accommodation container 9 has been mounted on the mounting part 20, a sensor configured to detect that the mounting part 20 has been arranged at the dock position B2, a sensor configured to detect that the door part 40 has been arranged at the closed position D1, etc.) at appropriate positions. The control part 70 is electrically connected to the respective sensors to control the respective parts based on the detection information obtained from the respective sensors.

### Step S1: Accommodation Container Loading Step

First, in a state where the mounting part 20 is arranged at the separation position B1 and the door part 40 is arranged at the closed position D1, the accommodation container 9 (e.g., the accommodation container 9 containing unprocessed substrates W) is transferred by an external robot such as an AMHS, a PGV, or an OHT and mounted on the mounting part 20 (FIG. 7A). The accommodation container 9 mounted on the mounting part 20 is guided to a predetermined position by the positioning pins 21 provided on the mounting part 20. In addition, the locking part 22 provided on the mounting part 20 is hooked onto the fixing portion provided on the bottom surface of the accommodation container 9, and the accommodation container 9 is fixed to the mounting part 20 at the predetermined position. Thereafter, if necessary, a specified gas is purged into the accommodation container 9 from the gas nozzle 23 via the gas supply valve, and the gas inside the accommodation container 9 is exhausted from another gas nozzle 23 via the gas exhaust valve, such that the inside of the accommodation container 9 is replaced with the specified gas and the pressure in the accommodation container 9 is regulated to a specified value.

### Step S2: Mounting Part Movement Step

When the accommodation container 9 is mounted on the mounting part 20, the mounting part drive mechanism 30 moves the mounting part 20 from the separation position B1 to the dock position B2 (FIG. 7B). That is, the mounting part drive mechanism 30 moves the mounting part 20 toward the base part 10 (rearward), bringing the opening portion 13 (and thus the door part 40 that closes the opening portion) provided in the base part 10 closer to the lid 92. In a state where the mounting part 20 is arranged at the dock position B2, the jaw portion 911 of the accommodation container 9 mounted on the mounting part 20 abuts against the front surface of the base part 10 (docking).

### Step S3: Lid Holding Step

When the mounting part 20 is arranged at the dock position B2, the lid holding mechanism 41 then causes the lid 92 to be held on the door part 40. That is, with the mounting part 20 being mounted at the dock position B2 and the jaw portion 911 of the accommodation container 9 mounted on the mounting part 20 being in contact with the base part 10, the lid 92 of the accommodation container 9 is in contact with or sufficiently close (at least close enough for the lid holding mechanism 41 to hold the lid 92 on the door part 40) to the door part 40 that is closing the opening portion 13 (i.e., arranged at the closed position D1). In this state, the lid holding mechanism 41 integrally connects the lid 92 to the door part 40, thereby causing the lid 92 to be held on the door part 40. The lid holding mechanism 41 also performs the unlatching between the container body 91 and the lid 92 of the accommodation container 9.

### Step S4: Opening Step

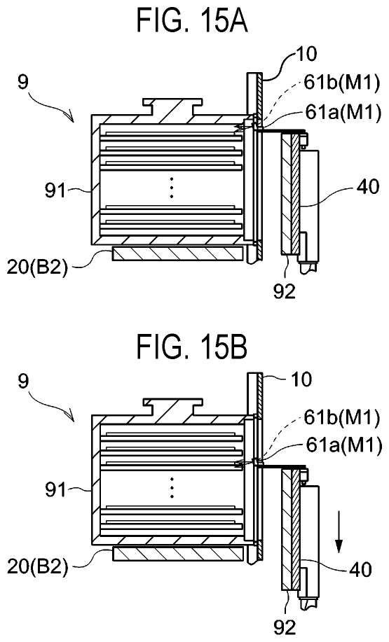

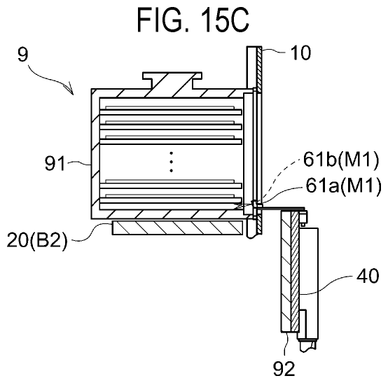

Then, the door part drive mechanism 50 moves the door part 40 together with the lid 92 held by the door part 40 from the closed position D1 to the open position D2. Specifically, the door part drive mechanism 50 moves the door part 40 from the closed position D1 rearward to an operation conversion position Dt (FIG. 7C), and then moves the door part 40 downward to the open position D2 (FIG. 7D). As will be described later, while the door part 40 is being lowered from the operation conversion position Dt to the open position D2, a mapping operation is performed by the mapping part 60 (FIGS. 15A to 15C).

By moving the door part 40 from the closed position D1, the inside of the container body 91 is brought into communication with the transfer space V through the opening portion 13. When the door part 40 is arranged at the open position D2, the transfer robot 82 arranged in the transfer space V takes out the substrate W accommodated in the container body 91 and loads the substrate W into the processing apparatus M. In addition, the transfer robot 82 unloads the substrate W that has been subjected to a predetermined process in the processing apparatus M from the processing apparatus M, and accommodates the substrate W in the container body 91.

### Step S5: Closing Step

When a predetermined number of substrates W are contained in the container body 91, the door part drive mechanism 50 moves the door part 40 together with the lid 92 held by the door part 40 from the open position D2 to the closed position D1. Specifically, the door part drive mechanism 50 raises the door part 40 from the open position D2 to the operation conversion position Dt (FIG. 7C), and then moves the door part 40 forward from there to the closed position D1 (FIG. 7B). By arranging the door part 40 at the closed position D1, the lid 92 held by the door part 40 is attached to the container body 91.

### Step S6: Lid Holding Release Step

When the lid 92 is attached to the container body 91, the lid holding mechanism 41 performs the latching between the container body 91 and the lid 92. The lid holding mechanism 41 also releases the connection between the door part 40 and the lid 92, thereby separating the door part 40 and the lid 92 (releasing the holding state).

### Step S7: Mounting Part Movement Step

Next, the mounting part drive mechanism 30 moves the mounting part 20 from the dock position B2 to the separation position B1 (FIG. 7A).

### Step S8: Accommodation Container Unloading Step

When the mounting part 20 is arranged at the separation position B1, the locking part 22 provided on the mounting part 20 is released, and the accommodation container 9 is released from the mounting part 20. The accommodation container 9 is then unloaded by an external robot.

### 5. Mapping Part

### 5-1. Configuration

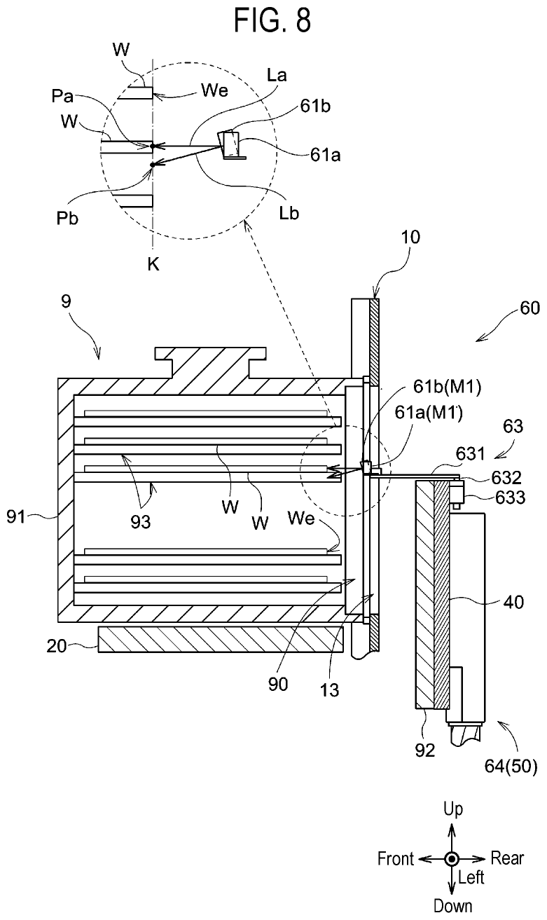

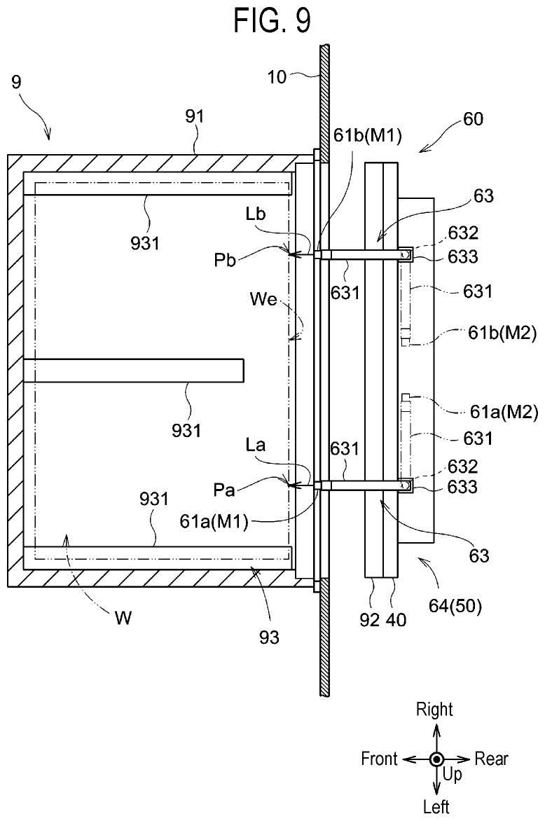

Next, a configuration of the mapping part 60 will be described with reference to FIGS. 8 to 10. FIG. 8 is a side cross-sectional view showing the vicinity of the opening portion 13. FIG. 9 is a top cross-sectional view showing the vicinity of the opening portion 13. FIG. 10 is a block diagram showing the configuration of the mapping part 60.

The mapping part (mapping device) 60 includes a first mapping sensor 61a, a second mapping sensor 61b, a first off-delay timer 62a, a second off-delay timer 62b, a local drive mechanism 63, a sensor drive mechanism 64, and a mapping processor 65.

### (Mapping Sensors 61a and 61b)

Each of the mapping sensors 61a and 61b detects an end surface We (an end surface located on the side of the opening 90) of a substrate W (hereinafter referred to as an “accommodated substrate W”) accommodated in the container body 91 of the accommodation container 9 mounted on the mounting part 20, at a position where each of the mapping sensors 61a and 61b faces the end surface We.

Each of the mapping sensors 61a and 61b is, for example, a reflective photoelectric sensor including a light emitting part and a light receiving part. The light emitting part may be configured to include various light emitting elements, and the light receiving part may be configured to include various light receiving elements. The light (detection light) emitted from the light emitting part may be any type of light. For example, the detection light may be visible light or infrared light. The detection light may be a beam (line light), and may be laser light, for example. Furthermore, the light emitting part and the light receiving part may be built into one sensor amplifier.

Each of the mapping sensors 61a and 61b, while arranged at a detection position M1, which will be described later, emits (irradiates) detection light forward from the light emitting part thereof. An optical axis of each of the mapping sensors 61a and 61b, i.e., a path (detection line) La or Lb of the detection light emitted from the light emitting part, intersects with a plane (detected plane) K on which the end surfaces We of a plurality of accommodated substrates W arranged in the up-down direction are located. In a case where the end surface We of the accommodated substrate W is located at a position where the detection line La or Lb intersects with a detection plane K (i.e., a point on the detection plane K at which the detection light from each of the mapping sensor 61a and 61b is emitted) (hereinafter also referred to as a “detection point Pa or Pb”), the detection light is reflected by the end surface We. The reflected light is then detected by the light receiving part of each of the mapping sensors 61a and 61b. In other words, each of the mapping sensors 61a and 61b detects the end surface We of the accommodated substrate W at the detection point Pa or Pb.

Each of the mapping sensors 61a and 61b outputs an on signal when the detection light is detected by the light receiving part. That is, each of the mapping sensors 61a and 61b outputs an on signal when the end surface We of the accommodated substrate W is detected at the detection point Pa or Pb. Furthermore, each of the mapping sensors 61a and 61b outputs an OFF signal when no detection light is detected by the light receiving part. That is, each of the mapping sensors 61a and 61b outputs an OFF signal when the end surface We of the accommodated substrate W is not detected at the detection point Pa or Pb. As will be described later, the OFF signal output from each of the mapping sensors 61a and 61b is delayed by a predetermined delay time Da or Db and then input to the mapping processor 65.

Each of the mapping sensors 61a and 61b is provided on the door part 40. The two mapping sensors 61a and 61b are arranged, for example, separately on one side and the other side of the door part 40 in the left-right direction. In other words, the two mapping sensors 61a and 61b are arranged separately on one side and the other side of the end surface We of the accommodated substrate W in an extension direction thereof.

The first mapping sensor 61a and the second mapping sensor 61b are arranged at the same position in the up-down direction (i.e., at the same height). The first mapping sensor 61a and the second mapping sensor 61b are arranged in such postures in which the optical axis (detection line Lb) of the second mapping sensor 61b is inclined downward with respect to the optical axis (detection line La) of the first mapping sensor 61a. Specifically, for example, the first mapping sensor 61a is arranged is such a posture in which the detection line La extends in the horizontal direction, and the second mapping sensor 61b is arranged in such a posture in which the detection line Lb extends obliquely downward. Therefore, the detection point (second detection point) Pb of the second mapping sensor 61b is located lower than the detection point (first detection point) Pa of the first mapping sensor 61a.

### (Off-Delay Timers 62a and 62b)

The first off-delay timer 62a is located between the first mapping sensor 61a and the mapping processor 65 to delay the off signal output from the first mapping sensor 61a by a predetermined delay time (first delay time) Da and to input the delayed off signal to the mapping processor 65. Meanwhile, the second off-delay timer 62b is located between the second mapping sensor 61b and the mapping processor 65 to delay the off signal output from the second mapping sensor 61b by a predetermined delay time (second delay time) Db, which is longer than the first delay time Da, and to input the delayed off signal to the mapping processor 65.

Each of the off-delay timers 62a and 62b may be realized in any manner. For example, each of the off-delay timers 62a and 62b may be circuits realized by hardware, such as dedicated logic circuits (e.g., dedicated processors) and the like. The off-delay timers 62a and 62b may be integrated with the mapping sensors 61a and 61b to constitute a part of the sensor module (i.e., a circuit built into the sensor module), or may be realized in the control part 70.

### (Local Drive Mechanism 63)

The local drive mechanism 63 moves each of the mapping sensors 61a and 61b with respect to the door part 40. The local drive mechanism 63 is provided between each of the mapping sensors 61a and 61b and the door part 40. In other words, each of the mapping sensors 61a and 61b is supported by the door part 40 via the local drive mechanism 63. The local drive mechanism 63 moves each of the mapping sensors 61a and 61b toward or away from the end surface We of the accommodated substrate W, thereby moving each of the mapping sensors 61a and 61b between a position M1 (detection position) relatively close to the end surface We of the substrate W and a position M2 (retracted position) relatively far from the end surface We of the substrate W.

Specifically, the local drive mechanism 63 includes, for example, an arm 631 extending in a horizontal plane while supporting one of the mapping sensors 61a and 61b at its tip, a rod 632 connected at its upper end to a base end portion of the arm 631 and extending vertically, and a drive part (e.g., a rotary actuator) 633 configured to rotate the rod 632 around its axis. The drive part 633 is attached to the rear surface of the door part 40 near an upper edge thereof, and the upper end of the rod 632 and hence the arm 631 supported thereon are arranged at a position higher than the upper edge of the door part 40. In this configuration, when the rod 632 rotates in response to the drive of the drive part 633, the arm 631 horizontally rotates around the rod 632 in a space above the door part 40. As a result, the mapping sensors 61a and 61b supported at the tip of the arm 631 move along an arc-shaped trajectory toward and away from the end surface We of the accommodated substrate W. For example, positions of the mapping sensors 61a and 61b when the arm 631 is in a posture in which the arm 631 protrudes forward of the door part 40 and extends along the front-rear direction (a posture in which an extension direction is orthogonal to the upper edge of the door part 40) are defined as the detection position M1. On the other hand, positions of the mapping sensors 61a and 61b when the arm 631 is in a posture in which the arm 631 extends along the left-right direction (a posture in which the extension direction is parallel to the upper edge of the door part 40 on a rear side thereof) are defined as the retracted position M2.

### (Sensor Drive Mechanism 64)

The sensor drive mechanism 64 moves each of the mapping sensors 61a and 61b in the arrangement direction of the accommodated substrates W. Here, each of the mapping sensors 61a and 61b is provided on the door part 40, which is provided with a door part drive mechanism 50 configured to move the door part 40 in the front-rear direction and the up-down direction. Therefore, when the door part drive mechanism 50 moves the door part 40 in the up-down direction, each of the mapping sensors 61a and 61b is moved along with the door part 40 in the arrangement direction of the accommodated substrates W. In other words, the door part drive mechanism 50 serves as the sensor drive mechanism 64 configured to move each of the mapping sensors 61a and 61b in the arrangement direction of the accommodated substrates W.

### (Mapping Processor 65)

The mapping processor 65 determines the accommodation state of the accommodated substrate W based on a signal Qa (hereinafter also referred to as a “first input signal”) input to the mapping processor 65 from the first mapping sensor 61a via the first off-delay timer 62a, and a signal Qb (hereinafter also referred to as a “second input signal”) input to the mapping processor 65 from the second mapping sensor 61b via the second off-delay timer 62b.

The mapping processor 65 is a functional element realized, for example, by the control part 70. An actual form of the mapping processor 65 may be, for example, a calculation part realized by the CPU 71 executing a program stored in the memory part 74 in the control part 70, or may be a circuit realized by hardware such as a dedicated logic circuit (e.g., a dedicated processor).

### 5-2. First Input Signal

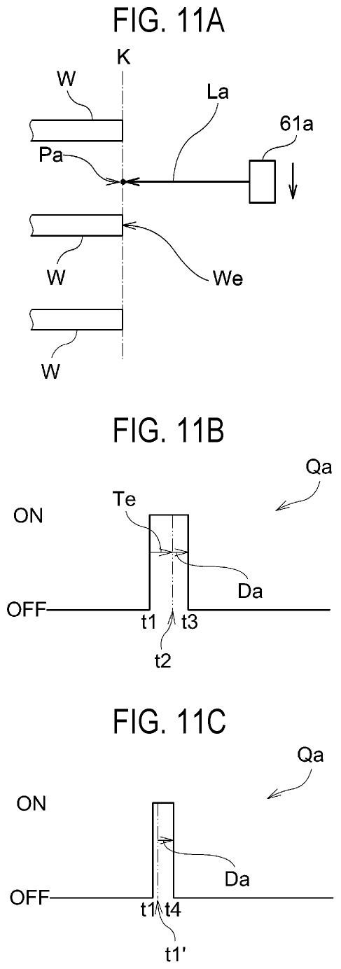

The signal (first input signal) Qa input from the first mapping sensor 61a via the first off-delay timer 62a to the mapping processor 65 will be described with reference to FIGS. 11A to 11C. FIGS. 11A to 11C are diagrams for explaining the first input signal Qa.

When the first mapping sensor 61a is arranged at the detection position M1 and, for example, is lowered while emitting detection light, the first detection point Pa moves in the arrangement direction of the accommodated substrates W. When the first detection point Pa reaches a height of the upper edge of the end surface We of the accommodated substrate W, at time t1, the signal output from the first mapping sensor 61a is switched from an off signal to an on signal. The on signal output from the first mapping sensor 61a is input directly to the mapping processor 65 without any delay. In other words, at time t1 when the first detection point Pa reaches the height of the upper edge of the end surface We of the accommodated substrate W, the first input signal Qa rises (is switched from an off signal to an on signal).

When a predetermined time (traversing time) Te has elapsed since the first detection point Pa reached the height of the upper edge of the end surface We of the accommodated substrate W, the first detection point Pa reaches the height of a lower edge of the end surface We of the accommodated substrate W. The traversing time Te is a time required for the detection points Pa and Pb to traverse the end surface We of the accommodated substrate W (i.e., a time obtained by dividing a thickness of one substrate W by a movement speed of the mapping sensors 61a and 61b). When the first detection point Pa reaches the height of the lower edge of the end surface We of the accommodated substrate W, at time t2, the signal output from the first mapping sensor 61a is switched from an on signal to an off signal. The off signal output from the first mapping sensor 61a is delayed by the first off-delay timer 62a by a first delay time Da and is input to the mapping processor 65. In other words, the first input signal Qa falls (is switched from an on signal to an off signal) at time t3, which is delayed by the first delay time Da from time t2 when the first detection point Pa reaches the height of the lower edge of the end surface We of the accommodated substrate W (FIG. 11B).

In reality, due to various factors such as unevenness of the end surface We of the accommodated substrate W, chattering (a phenomenon in which the output signal is switched between an on state and an off state at a high speed) may occur in the signal output from the first mapping sensor 61a. When the chattering occurs, the signal output from the first mapping sensor 61a may be switched to an off signal (indicated by the two-dot chain line in FIG. 11C) at time t1′ immediately after time t1 when the first detection point Pa reaches the upper edge of the end surface We of the accommodated substrate W (i.e., even though the first detection point Pa has not yet reached the height of the lower edge of the end surface We of the accommodated substrate W). In this case, the off signal output from the first mapping sensor 61a is delayed by the first delay time Da by the first off-delay timer 62a and is input to the mapping processor 65. In other words, the first input signal Qa falls at time t4, which is delayed by the first delay time Da from time t1′ immediately after time t1 when the first detection point Pa reaches the height of the upper edge of the end surface We of the accommodated substrate W (FIG. 11C).

In this way, when the first delay time Da is set for the off signal output from the first mapping sensor 61a, even in the case where chattering occurs in the signal output from the first mapping sensor 61a, this chattering is not directly reflected in the first input signal Qa. In other words, by setting the first delay time Da, an influence of chattering is reduced or eliminated. The first delay time Da is preferably a sufficiently short time within a range in which the influence of chattering is reduced or eliminated. As an example, the first delay time Da is set to 10 to 20 msec (milliseconds), preferably 15 msec.

### 5-3. Second Input Signal

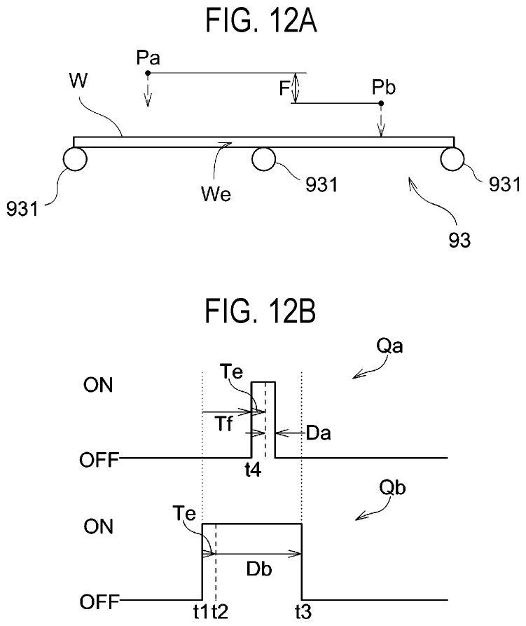

The signal (second input signal) Qb input from the second mapping sensor 61b via the second off-delay timer 62b to the mapping processor 65 will be described with reference to FIGS. 12A to 14C. Each of FIGS. 12A to 14C is a diagram for explaining a relationship between the posture of the accommodated substrate W and a timing at which the first input signal Qa and the second input signal Qb are switched.

In the following, “the substrate W is normally supported” refers to a state in which all of the multiple (three in the illustrated example) support rods 931 constituting one shelf 93 support the same substrate W. In other words, “the substrate W is not normally supported” refers to a state in which only some of the multiple support rods 931 constituting one shelf 93 support the substrate W and the rest thereof do not support the substrate W (hereinafter also referred to as “cross abnormality state”). For example, a state in which the substrate W is supported across multiple shelves 93 is also one form of the cross abnormality state.

(i) When Properly Supported without Bending

When the first mapping sensor 61a and the second mapping sensor 61b are both arranged at the detection position M1 and, for example, lowered while emitting detection light, the first detection point Pa and the second detection point Pb are moved in the arrangement direction of the accommodated substrates W. As described above, the second detection point Pb is located lower than the first detection point Pa. In other words, the second detection point Pb is located on a downstream side of the first detection point Pa in the direction of the movement. Therefore, the second detection point Pb is moved ahead of the first detection point Pa in the arrangement direction of the accommodated substrates W.

Now, it is assumed that the accommodated substrate W is supported normally without bending (without bending or warping) (FIG. 12A). In this case, the second detection point Pb reaches the height of the upper edge of the end surface We of the accommodated substrate W ahead of the first detection point Pa. When the second detection point Pb reaches the height of the upper edge of the end surface We of the accommodated substrate W, at time t1, the signal output from the second mapping sensor 61b is switched from an off signal to an on signal. The on signal output from the second mapping sensor 61b is input directly to the mapping processor 65 without any delay. In other words, the second input signal Qb rises at time t1 when the second detection point Pb reaches the height of the upper edge of the end surface We of the accommodated substrate W.

When the second detection point Pb reaches the height of the lower edge of the end surface We of the accommodated substrate W after a traversing time Te has elapsed since the second detection point Pb reached the height of the upper edge of the end surface We of the accommodated substrate W, the signal output from the second mapping sensor 61b is switched from an on signal to an off signal at time t2. The off signal output from the second mapping sensor 61b is delayed by the second off-delay timer 62b by the second delay time Db and is input to the mapping processor 65. In other words, the second input signal Qb falls at time t3, which is delayed by the second delay time Db from time t2 at which the second detection point Pb reached the height of the lower edge of the end surface We of the accommodated substrate W.

On the other hand, when a predetermined time (fixed offset time) Tf has elapsed since the second detection point Pb reached the height of the upper edge of the end surface We of the accommodated substrate W, the first detection point Pa reaches the height of the upper edge of the end surface We of the accommodated substrate W. The fixed offset time Tf is a time corresponding to an offset width F of the detection points Pa and Pb in the height direction (i.e., a time obtained by dividing the offset width F by the movement speed of the mapping sensors 61a and 61b). When the first detection point Pa reaches the height of the upper edge of the end surface We of the accommodated substrate W, at time t4, the signal output from the first mapping sensor 61a is switched from an off signal to an on signal. The on signal output from the first mapping sensor 61a is also input directly to the mapping processor 65 without any delay. In other words, the first input signal Qa rises at time t4 at which the first detection point Pa reached the height of the upper edge of the end surface We of the accommodated substrate W.

Here, the second delay time Db is defined so that, when the accommodated substrate W is supported normally without bending, the second input signal Qb has not yet fallen when the first input signal Qa rises. For example, the second delay time Db is set to be longer than the fixed offset time Tf. Therefore, when the accommodated substrate W is supported normally without bending, the second input signal Qb first rises (this time will hereinafter also be referred to as “first reference time t1”), then the first input signal Qa rises (this time will hereinafter also be referred to as “second reference time t4”), and then the second input signal Qb falls (this time will hereinafter also be referred to as “third reference time t3”).

### (ii) When the First Detection Point Pa is on the Lower Side

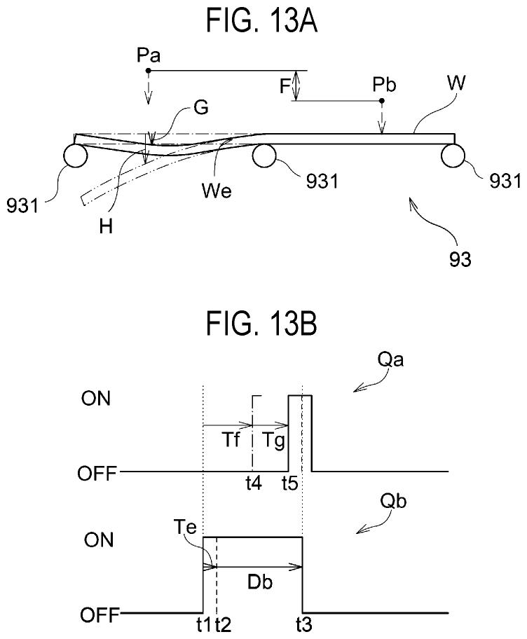

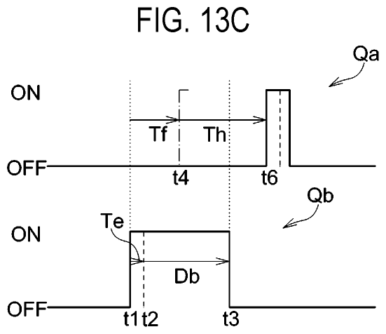

Next, it is assumed that the accommodated substrate W is supported normally while bending relatively downward on the side of the first detection point Pa (while bending or warping downward) (e.g., as indicated by the solid line in FIG. 13A). In this case, compared to a case where the accommodated substrate W is supported normally without bending (as indicated by the one-dot chain line in FIG. 13A), a timing at which the first detection point Pa reaches the height of the upper edge of the end surface We of the accommodated substrate W is delayed by a delay time Tg corresponding to bending width G of the accommodated substrate W. Therefore, the time at which the first input signal Qa rises is time t5, which is delayed from the second reference time t4 by the delay time Tg corresponding to the bending width G (FIG. 13B).

Meanwhile, it is assumed that, when the accommodated substrate W is not supported by the support rod 931 on the side of the first detection point Pa, the accommodated substrate W hangs down obliquely on the side of the first detection point Pa (as indicated by the two-dot chain line in FIG. 13A). Therefore, compared to a case where the accommodated substrate W is supported normally without bending (as indicated by the one-dot chain line in FIG. 13A), the timing at which the first detection point Pa reaches the height of the upper edge of the end surface We of the accommodated substrate W is delayed by a delay time Th corresponding to a hanging width H of the accommodated substrate W. Therefore, the time at which the first input signal Qa rises is time t6, which is delayed from the second reference time t4 by the delay time Th corresponding to the hanging width H (FIG. 13C).

There is a limit in the bending width G that may occur when the accommodated substrate W is supported normally while bending. A maximum possible bending width G can be predicted from a thickness and a size of the accommodated substrate W, an arrangement interval of the support rods 931, and the like. Here, for example, the positions of the mapping sensors 61a and 61b are defined so that the positions of the detection points Pa and Pb are sufficiently close to the end of the end surface We. The maximum bending width G at the positions through which the detection points Pa and Pb pass is smaller than the hanging width H. Therefore, the delay time Tg corresponding to the bending width G is shorter than the delay time Th corresponding to the hanging width H. Here, the second delay time Db is defined so that even in a case where the first input signal Qa rises with a delay of the delay time Tg corresponding to the bending width G from the second reference time t4, the second input signal Qb has not yet fallen at the time at which the first input signal Qa rises. Meanwhile, the second delay time Db is defined so that when the first input signal Qa rises after a delay of a delay time Th corresponding to the hanging width H from the second reference time t4, the second input signal Qb has already fallen at the time at which the first input signal Qa rises. For example, the second delay time Db is set to a time approximately equal to a sum of the fixed offset time Tf and the delay time Tg corresponding to the maximum bending width G. As an example, the second delay time Db is set to 50 to 150 msec (milliseconds), preferably 100 msec.

(iii) When the Second Detection Point Pb is on the Lower Side

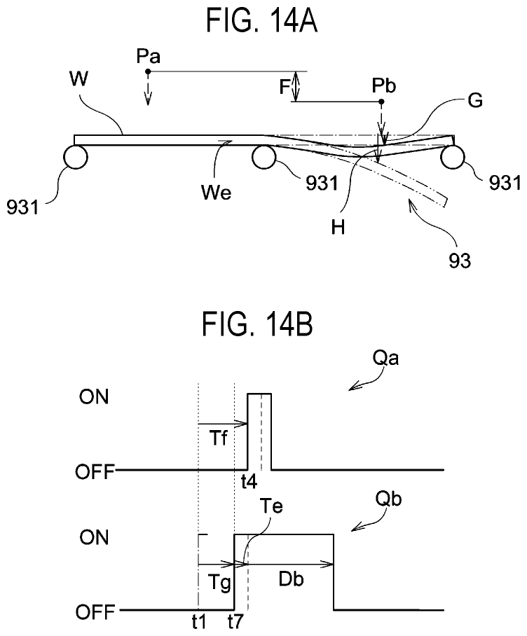

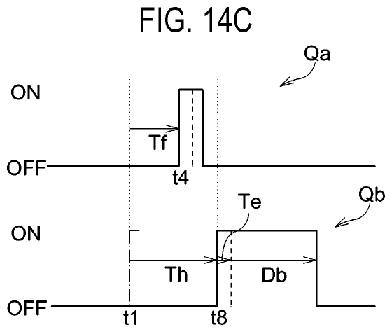

Next, it is assumed that the accommodated substrate W is supported normally while bending relatively downward on the side of the second detection point Pb (as indicated by the solid line in FIG. 14A). In this case, compared to a case where the accommodated substrate W is supported normally without bending (as indicated by the one-dot chain line in FIG. 14A), a timing at which the second detection point Pb reaches the height of the upper edge of the end surface We of the accommodated substrate W is delayed by a delay time Tg corresponding to the bending width G of the accommodated substrate W. Therefore, the time at which the second input signal Qb rises is time t7, which is delayed from the first reference time t1 by the delay time Tg corresponding to the bending width G (FIG. 14B).

Meanwhile, it is assumed that when the accommodated substrate W is not supported by the support rod 931 on the side of the second detection point Pb, the accommodated substrate W hangs down obliquely on the side of the second detection point Pb (as indicated by the two-dot chain line in FIG. 14A). Therefore, compared to a case where the accommodated substrate W is supported normally without bending (as indicated by the two-dot chain line in FIG. 14A), the timing at which the second detection point Pb reaches the height of the upper edge of the end surface We of the accommodated substrate W is delayed by a delay time Th corresponding to the hanging width H of the accommodated substrate W. Therefore, the time at which the second input signal Qb rises is time t8, which is delayed from the first reference time t1 by the delay time Th corresponding to the hanging width H (FIG. 14C).

As described above, at the positions through which the detection points Pa and Pb pass, the maximum bending width G is smaller than the hanging width H, and the delay time Tg corresponding to the bending width G is shorter than the delay time Th corresponding to the hanging width H. Here, the fixed offset time Tf (specifically, the offset width F of the detection points Pa and Pb in the height direction) is defined so that even when the second input signal Qb rises with a delay of the delay time Tg corresponding to the bending width G from the first reference time t1, the first input signal Qa has not yet fallen (more preferably, the first input signal Qa has not yet risen) at the time at which the second input signal Qb rises. Meanwhile, the fixed offset time Tf (specifically, the offset width F) is defined so that when the second input signal Qb rises with a delay of the delay time Th corresponding to the hanging width H from the first reference time t1, the first input signal Qa has already fallen at the time at which the second input signal Qb rises. For example, the offset width F is set to a value greater than the maximum bending width G and smaller than the hanging width H. As an example, in a case where the thickness of the substrate W is about 0.8 mm and the maximum bending width G is about 1 to 1.5 mm, the offset width F is set to, for example, 2 to 3 mm.

As described above, the second delay time Db and the offset width F are adjusted so that when the accommodated substrate W is supported normally (when the accommodated substrate W is not in the cross abnormality state), even in a case where the accommodated substrate W is bent or warped, a time period during which the first input signal Qa is in on state and a time period during which the second input signal Qb is in on state are at least partially overlapped with each other (FIGS. 12B, 13B, and 14B), and when the accommodated substrate W is in the cross abnormality state, the time period during which the first input signal Qa is in on state and the time period during which the second input signal Qb is in on state are not overlapped with each other (FIGS. 13C and 14C). In other words, the second delay time Db and the offset width F are adjusted so that the relationship between the timings at which the input signals Qa and Qb are switched on and off varies depending on whether the accommodated substrate W is supported normally (whether the accommodated substrate W is in the cross abnormality state or not). Accordingly, it is possible to determine whether the accommodated substrate W is supported normally, based on the relationship between the timings at which the input signals Qa and Qb are switched on and off.

### 5-4. Mapping Operation

Next, an overview of the mapping operation will be described with reference to FIGS. 15A to 15C. FIGS. 15A to 15C are diagrams for explaining the movement of the mapping sensors during the mapping operation.

As described above, in the load port 1, in the opening step (step S4), the door part drive mechanism 50 moves the door part 40 together with the lid 92 held by the door part 40 from the closed position D1 to the open position D2 via the operation conversion position Dt (FIGS. 7B, 7C, and 7D). In this opening step (step S4), when the door part 40 is slightly lowered from the operation conversion position Dt and the detection points and Pa and Pb of the mapping sensors 61a and 61b are arranged at a height slightly higher than the accommodated substrate W supported by the uppermost shelf 93, each of the mapping sensors 61a and 61b is moved from the retracted position M2 to the detection position M1 (FIG. 15A). Thereafter, by further lowering the door part 40, each of the mapping sensors 61a and 61b is moved in the arrangement direction of the accommodated substrates W while emitting detection light in a state in which each of the mapping sensors 61a and 61b is arranged at the detection position M1 (FIG. 15B). That is, each of the mapping sensors 61a and 61b detects the end surface We of each accommodated substrate W from a position facing the end surface We while moving in the arrangement direction of the accommodated substrates W (detection step). When the detection points and Pa and Pb of the mapping sensors 61a and 61b are arranged at a height slightly lower than the accommodated substrate W supported by the lowermost shelf 93 (FIG. 15C), each of the mapping sensors 61a and 61b is moved from the detection position M1 to the retracted position M2. Each of the mapping sensors 61a and 61b may be maintained in a state of emitting detection light, for example, while the load port 1 is operating. Alternatively, each of the mapping sensors 61a and 61b may be controlled to start emitting light when it is moved to the detection position M1, and to stop emitting light when it is moved to the retracted position M2.

As described above, each of the mapping sensors 61a and 61b is moved in the arrangement direction of the accommodated substrates W while emitting detection light in a state in which each of the mapping sensors 61a and 61b is arranged at the detection position MI, whereby a group of accommodated substrates W (a group of accommodated substrates W including the accommodated substrate W supported on the uppermost shelf 93 to the accommodated substrate W supported on the lowermost shelf 93) is scanned in the arrangement direction of thereof by the detection lines La and Lb. That is, the end surfaces We of the group of accommodated substrates W are detected by each of the mapping sensors 61a and 61b. While the group of accommodated substrates W is scanned by the detection lines La and Lb, the signals output from the mapping sensors 61a and 61b are input to the mapping processor 65 via the off-delay timers 62a and 62b, respectively. The mapping processor 65 determines the accommodation state of the accommodated substrates W based on the signals (input signals) Qa and Qb input to the mapping processor 65 from the mapping sensors 61a and 61b via the off-delay timers 62a and 62b respectively (mapping processing step).

### 5-5. Mapping Process

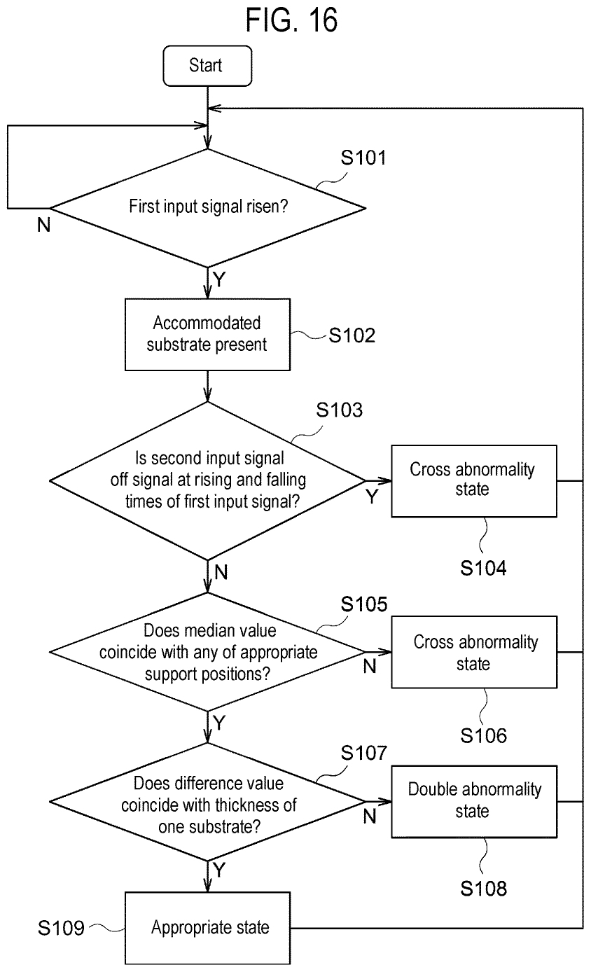

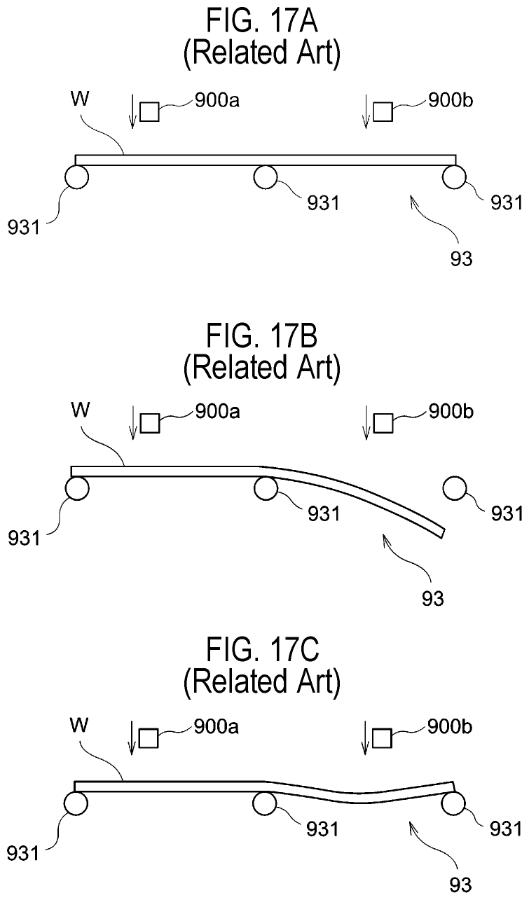

Next, a mapping process will be described with reference to FIG. 16. FIG. 16 is a diagram showing a flow of the mapping process.

Here, “determination of the accommodation state” includes, for example, determination of presence or absence of an accommodated substrate W (counting of the number of substrates) and determination of a support state of the accommodated substrate W. In addition, the “determination of the support state” includes, for example, determination as to whether the support state of the accommodated substrate W is a normal state (a state in which one substrate W is normally supported on one shelf 93), a cross abnormality state (a state in which only some of the support rods 931 constituting one shelf 93 support the substrate W and the rest thereof do not support the substrate W), or a double abnormality state (a state in which two or more substrates W are supported on one shelf 93).

### (i) Determination of Presence or Absence

In a case where the first detection point Pa reaches the height of the upper edge of the end surface We of the accommodated substrate W while the first mapping sensor 61a and the second mapping sensor 61b are being moved in the arrangement direction of the accommodated substrate W while emitting detection light in a state in which the first mapping sensor 61a and the second mapping sensor 61b are both arranged at the detection position M1, the first input signal Qa rises at that time. In a case where the first input signal Qa rises (YES in step S101), the mapping processor 65 specifies the height of the first detection point Pa at the time of the rise and determines that the accommodated substrate W is present at that height (step S102). In a case where it is not determined that the accommodated substrate W is present at a height corresponding to any shelf 93, it is highly likely that the accommodated substrate W is not supported on that shelf 93 (there is no accommodated substrate W), or that the accommodated substrate W supported on that shelf 93 is in a cross abnormality state.

The heights of the first detection point Pa and the second detection point Pb at each time can be specified in any suitable manner. For example, in a case where the door part drive mechanism 50, which serves as the sensor drive mechanism 64, includes a numerically controllable drive source (e.g., a stepping motor), the height of the door part 40 at each time, and therefore the heights of the mapping sensors 61a and 61b, and therefore the heights of the detection points Pa and Pb, can be specified based on a command value given to the drive source (e.g., based on a counter value (number of steps) of operating pulses given to the stepping motor). Furthermore, in a case where an encoder is provided in the motor that serves as the drive source of the door part drive mechanism 50, the height of the door part 40 at each time can be specified based on an output value of the encoder.

### (ii) Detection of Cross Abnormality State

In a case where it is determined that an accommodated substrate W is present, the mapping processor 65 determines whether the substrate W is in a cross abnormality state. Here, there is illustrated a case in which the determination of whether the cross abnormality state exists is performed in two stages.

### (First-Stage Determination)

As described above, the second delay time Db and the offset width F are adjusted so that when the accommodated substrate W is supported normally (when the accommodated substrate W is not in the cross abnormality state), even in a case where the accommodated substrate W is bent or warped, the time period during which the first input signal Qa is in on state and the time period during which the second input signal Qb is in on state are at least partially overlapped with each other (FIGS. 12B, 13B and 14B), and so that when the accommodated substrate W is in the cross abnormality state, the time period during which the first input signal Qa is in on state and the time period during which the second input signal Qb is in on state are not overlapped with each other (FIGS. 13C and 14C). Therefore, the mapping processor 65 determines, for example, whether the second input signal Qb is an off signal at both the rising and falling times of the first input signal Qa (step S103). In a case where a positive determination result is obtained here, that is, in a case where the second input signal Qb is an off signal at both the time at which the first input signal Qa rises and the time at which the first input signal Qa falls (YES in step S103), the mapping processor 65 determines that the accommodated substrate W is not supported normally (is in the cross abnormality state) (step S104). On the other hand, in a case where a negative determination result is obtained, that is, in a case where the second input signal Qb is an on signal at either or both of the time at which the first input signal Qa rises and the time at which the first input signal Qa falls (NO in step S103), the mapping processor 65 determines that the accommodated substrate W is not in the cross abnormality state at least in the first-stage determination, and proceeds to the process of step S105.

### (Second-Stage Determination)

In a case where the accommodated substrate W is normally supported, a median value of the heights of the upper and lower edges of the end surface We of the accommodated substrate W (a center height of the end surface We) may sufficiently coincide with an appropriate support position corresponding to one of the shelves 93 (i.e., a position where the center height of the accommodated substrate W is to be arranged when the accommodated substrate W is appropriately supported on one of the shelves 93). On the other hand, in a case where the accommodated substrate W is in the cross abnormality state, the median value may not sufficiently coincide with any one of the appropriate support positions. Therefore, the mapping processor 65 determines whether the median value of the height of the first detection point Pa at the time at which the first input signal Qa rises and the height of the first detection point Pa at the time at which the first input signal Qa falls coincides with any one of the appropriate support positions within a predetermined tolerance (step S105). In a case where a negative determination result is obtained (NO in step S105), the mapping processor 65 determines that the accommodated substrate W is not normally supported (is in the cross abnormality state) (step S106). On the other hand, in a case where a positive determination result is obtained (YES in step S105), the mapping processor 65 determines that the accommodated substrate W is not in the cross abnormality state, and proceeds to the process of step S107.

The off signal output from the first mapping sensor 61a is delayed by the first delay time Da and input to the mapping processor 65. Therefore, the time at which the first input signal Qa falls may be delayed from the time at which the first detection point Pa of the first mapping sensor 61a reaches the height of the lower edge of the end surface We of the accommodated substrate W. In other words, the median value specified based on the first input signal Qa may deviate from the center height of the end surface We. However, as described above, the first delay time Da is set to be sufficiently short, and this deviation is sufficiently small compared to an arrangement interval of the shelves 93. Accordingly, by setting the first delay time Da, it is sufficiently unlikely that accuracy of the determination is reduced.

(iii) Detection of Double Abnormality State

In a case where it is determined that the accommodated substrate W is not in the cross abnormality state, the mapping processor 65 determines whether the accommodated substrate W is in a double abnormality state.

In a case where the accommodated substrate W is not in the double abnormality state, a difference between the heights of the upper and lower edges of the end surface We of the accommodated substrate W (the thickness of the end surface We) may be sufficiently consistent with the thickness of one substrate W. On the other hand, in a case where the accommodated substrate W is in the double abnormality state, the difference is likely to be equal to or more than twice the thickness of one substrate W. Therefore, the mapping processor 65 determines whether the difference between the height of the first detection point Pa at the time at which the first input signal Qa rises and the height of the first detection point Pa at the time at which the first input signal Qa falls coincides with an appropriate difference value corresponding to the thickness of one substrate W within a predetermined tolerance (step S107). In a case where a negative determination result is obtained (NO in step S107), the mapping processor 65 determines that the accommodated substrate W is in the double abnormality state (step S108). On the other hand, in a case where a positive determination result is obtained (YES in step S107), the mapping processor 65 determines that the accommodated substrate W is in an appropriate state (step S109).

The off signal output from the first mapping sensor 61a is delayed by the first delay time Da and then input to the mapping processor 65. Therefore, even in a case where the accommodated substrate W is not in the double abnormality state, there is a possibility that the difference value specified based on the first input signal Qa will be slightly larger than the thickness of one substrate W. Taking this into consideration, it is also preferable that the appropriate difference value to be compared with the difference value specified based on the first input signal Qa is set to a value slightly larger than the thickness of one substrate W. Needless to say, in a case where the accommodated substrate W is in the double abnormality state, there is a high possibility that the difference value specified based on the first input signal Qa will be slightly larger than a thickness of two substrates W. Therefore, even in a case where a value slightly larger than the thickness of one substrate W is set as the appropriate difference value, there is a sufficiently low possibility that the accuracy of determination will decrease.

### 6. Effects

The mapping part (mapping device) 60 includes the first mapping sensor 61a arranged on one side of the end surface We of the rectangular substrate W accommodated in the accommodation container 9 in the extension direction of the end surface We and configured to move in the arrangement direction of the substrate W and output the on signal upon detecting the end surface We at the first detection point Pa, the second mapping sensor 61b arranged on the other side of the end surface We in the extension direction and configured to move in the arrangement direction of the substrate W and output the on signal upon detecting the end surface We at the second detection point Pb on the downstream side of the first detection point Pa in the direction of the movement, and the mapping processor 65 configured to determine the accommodation state of the substrate W based on the first input signal Qa input from the first mapping sensor 61a and the second input signal Qb input from the second mapping sensor 61b via the off-delay timer (second off-delay timer) 62b configured to delay the off signal. According to this configuration, the offset width F in the direction of the movement of the first detection point Pa and the second detection point Pb (height direction in the above embodiment), and the delay time (second delay time) Db set for the off signal of the second mapping sensor 61b are adjusted such that the relationship between the timings at which the first input signal Qa and the second input signal Qb are switched on and off varies depending on the accommodation state to be determined (e.g., whether or not the accommodation state is the cross abnormal state). This makes it possible to determine the accommodation state of the substrate W with sufficient accuracy based on the relationship between the timings.

Furthermore, in the mapping part 60, the mapping processor 65 determines that the substrate W is not supported normally in a case where the second input signal Qb is the off signal at both the rising and falling times of the first input signal Qa. For example, it is also possible to determine the accommodation status of the substrate W by inputting the signals output from the respective mapping sensors, as they are (i.e., without setting a delay time for the off signal), to the control part without offsetting the detection points Pa and Pb in the direction of the movement, and analyzing the relationship between the timings at which the respective input signals are switched in the control part. However, such an analysis would increase a processing load on the control part and prolong the time required for determination. In contrast, with the above configuration, the accommodation status of the substrate W is determined by merely checking whether the second input signal Qb is the off signal at both the rising and falling times of the first input signal Qa, thereby enabling the accommodation status of the substrate W to be determined quickly while minimizing the processing load.

Furthermore, in the mapping part 60, the first input signal Qa is a signal input from the first mapping sensor 61a to the mapping processor 65 via the off-delay timer (first off-delay timer) 62a configured to delay the off signal, and the delay time (first delay time) Da set for the off signal output from the first mapping sensor 61a is shorter than the delay time (second delay time) Db set for the off signal output from the second mapping sensor 61b. According to this configuration, the first input signal Qa input to the mapping processor 65 is the off signal output from the first mapping sensor 61a with a relatively short first delay time Da set. Therefore, even in a case where chattering occurs in the signal output from the first mapping sensor 61a, an influence of the chattering is reduced or eliminated. Accordingly, the accuracy of determining the accommodation state is less likely to be reduced.

Furthermore, in the mapping part 60, the optical axis (detection line) Lb of the second mapping sensor 61b is inclined in the direction of the movement (a movement direction when the mapping sensors 61a and 61b are moved in the arrangement direction of the substrate W, which is the downward direction in the above embodiment) with respect to the optical axis (detection line La) of the first mapping sensor 61a. According to this configuration, the offset width F between the first detection point Pa and the second detection point Pb in the direction of the movement can be adjusted by adjusting the angle between the optical axis (detection line La) of the first mapping sensor 61a and the optical axis (detection line) Lb of the second mapping sensor 61b. Furthermore, according to this configuration, for example, the first mapping sensor 61a and the second mapping sensor 61b can be arranged at the same position in the direction of the movement, and the detection points Pa and Pb can be arranged at positions offset from each other in the direction of the movement. This simplifies a layout of the mapping part 60.

Furthermore, in the mapping part 60, the first mapping sensor 61 a and the second mapping sensor 61 b are provided on the door part 40. According to this configuration, for example, by utilizing the operation of moving the door part 40 from the closed position D1 to the open position D2, it is possible to move each of the mapping sensors 61a and 61b in the arrangement direction of the accommodated substrates W accommodated in the accommodation container 9. Accordingly, a configuration of the mapping part 60 can be simplified.

The mapping part 60 further includes a local drive mechanism 63 configured to move each of the mapping sensors 61a and 61b toward or away from the end surface We of the accommodated substrate W. According to this configuration, for example, while each of the mapping sensors 61a and 61b is not performing a detection operation for the end surface We of the accommodated substrate W, each of the mapping sensors 61a and 61b can be arranged at a position (retracted position) M2 relatively far from the end surface We of the accommodated substrate W so as not to interfere. When each of the mapping sensors 61a and 61b performs a detection operation for the end surface We of the accommodated substrate W, each of the mapping sensors 61a and 61b can be moved to a position (detection position) M1 relatively close to the end surface We of the accommodated substrate W. By each of the mapping sensors 61a and 61b detecting the end surface We of the accommodated substrate W from a position sufficiently close to the end surface We, the accommodation state of the accommodated substrate W can be determined with sufficient accuracy. That is, as a separation distance between each of the mapping sensors 61a and 61b and the end surface We of the accommodated substrate W becomes smaller, it is possible to specify the rising and falling edges of the signal output from each of the mapping sensors 61a and 61b more accurately. This improves the accuracy of determining the accommodation state (e.g., the accuracy of determining the presence or absence of the accommodated substrate W, and the accuracy of determining the support state). In addition, as the separation distance between each of the mapping sensors 61a and 61b and the end surface We of the accommodated substrate W becomes smaller, it is possible to detect an end surface We of a thin accommodated substrate W more accurately. Therefore, the accommodation state of the thin accommodated substrate W can be determined with sufficient accuracy.

### 7. Other Embodiments

In the above embodiment, the second detection point Pb may be arranged on a downstream side of the first detection point Pa in the direction of the movement of the mapping sensors 61a and 61b in the arrangement direction of the accommodated substrates W (i.e., the offset width F may be set) in any manner.

For example, the second mapping sensor 61b may be arranged on a downstream side of the first mapping sensor 61a in the direction of the movement, such that the second detection point Pb is arranged on the downstream side of the first detection point Pa in the direction of the movement. For example, when the mapping sensors 61a and 61b are lowered to move in the arrangement direction of the accommodated substrates W, the second mapping sensor 61b may be arranged at a lower position than the first mapping sensor 61a, such that the second detection point Pb is arranged on the downstream side of the first detection point Pa in the direction of the movement. In this case, the mapping sensors 61a and 61b may be arranged in the same posture (e.g., a posture in which the detection lines La and Lb extend in the horizontal direction).

Furthermore, for example, as in the above embodiment, when the first mapping sensor 61a and the second mapping sensor 61b are arranged at the same position in the direction of the movement but in different postures such that the second detection point Pb is arranged on the downstream side of the first detection point Pa in the direction of the movement, a combination of the postures of the mapping sensors 61a and 61b can be defined as appropriate. For example, the first mapping sensor 61a may be arranged in a posture such that the detection line La extends obliquely upward, and the second mapping sensor 61b may be arranged in a posture such that the detection line Lb extends in the horizontal direction. Alternatively, the first mapping sensor 61a may be arranged in a posture such that the detection line La extends obliquely upward, and the second mapping sensor 61b may be arranged in a posture such that the detection line Lb extends obliquely downward.

In the above embodiment, the first detection point Pa may be located at a lower position than the second detection point Pb. For example, when the mapping sensors 61a and 61b are raised and moved in the arrangement direction of the accommodated substrates W, the first detection point Pa may be located at a lower position than the second detection point Pb.

In the above embodiment, the off-delay timers 62a and 62b may be realized in any manner. For example, the off-delay timers 62a and 62b may be realized as a calculation part implemented by causing the CPU 71 to execute a program stored in the memory part 74 in the control part 70. Specifically, for example, the off signals output from the mapping sensors 61a and 61b may be input, as they are, to the control part 70 without being delayed, and then the off-delay timers 62a and 62b implemented herein may perform calculation processing to delay the off signals by the respective delay times Da and Db before inputting the off signals to the mapping processor 65.

In the above embodiment, the first off-delay timer 62a may be omitted. That is, the off signal output from the first mapping sensor 61a may be input, as they are, to the mapping processor 65 without being delayed.

In the above embodiment, the mapping sensors 61a and 61b are provided on the door part 40. However, the mapping sensors 61a and 61b may not be provided on the door part 40. For example, the mapping sensors 61a and 61b may be provided on a guide shaft (a guide shaft extending in the arrangement direction of the accommodated substrates W) provided separately from the door part 40 so as to be movable along the guide shaft, and a drive mechanism may be provided to move the mapping sensors 61a and 61b provided on the guide shaft along the guide shaft. The drive mechanism preferably includes a numerically controllable drive source (e.g., a stepping motor). In this case, the drive mechanism configured to move the mapping sensors 61a and 61b along the guide shaft serves as the sensor drive mechanism 64 configured to move the mapping sensors 61a and 61b in the arrangement direction of the accommodated substrates W. Moreover, for example, the mapping sensors 61a and 61b may be provided on the hand of the transfer robot 82. In this case, by raising and lowering the hand, the mapping sensors 61a and 61b provided on the hand are moved in the arrangement direction of the accommodated substrates W. That is, in this case, the drive mechanism configured to raise and lower the hand serves as the sensor drive mechanism 64 configured to move each of the mapping sensors 61a and 61b in the arrangement direction of the accommodated substrates W.

In the above embodiment, each of the mapping sensors 61a and 61b may detect a distance to the position where the detection light is reflected (may output a distance signal) when the detection light is detected by the light receiving part (so-called distance sensor). In this case, each of the mapping sensors 61a and 61b may output an on signal when the detected distance is equal to or less than a predetermined threshold value (e.g., a threshold value corresponding to the separation distance from each of the mapping sensors 61a and 61b to the detection plane K). In this case as well, when the end surface We of the accommodated substrate W is located at the detection point Pa or Pb of each of the mapping sensors 61a and 61b, each of the mapping sensors 61a and 61b outputs an on signal.

In the above embodiment, it is preferable that each of the mapping sensors 61a and 61b is arranged at a position offset from the support rods 931 that support the accommodated substrate W in the left-right direction. For example, the first mapping sensor 61a may be arranged between the left support rod 931 and the central support rod 931 in the left-right direction, and the second mapping sensor 61b may be arranged between the right support rod 931 and the central support rod 931 in the left-right direction. According to this configuration, the light reflected by the end surfaces of the support rods 931 will not be detected by the light receiving part.

In the above embodiment, the number of mapping sensors 61a and 61b provided may not be two. For example, three or more mapping sensors may be provided.

In the above embodiment, a shape and a size of the detection light (a shape and a size of an irradiation region) in each of the mapping sensors 61a and 61b may be any shape and size.

For example, the shape of the detection light may be circular, elliptical, square, or rectangular (e.g., a rectangular shape elongated in the extension direction of the end surface We of the accommodated substrate W). Furthermore, for example, the detection light may have a size approximately equal to the thickness of the accommodated substrate W. In addition, each of the mapping sensors 61a and 61b may be realized by a sensor (e.g., a proximity sensor) other than the photoelectric sensor.

In the above embodiment, various values used for determination in the mapping process (for example, a value used to determine whether or not the substrate W is in the cross abnormality state (e.g., a proper support position), a value used to determine whether or not the substrate W is in the double abnormality state (e.g., a proper difference value), etc.) may be set individually depending on the thickness of the substrate W to be determined. In other words, the values used for determination may be changed depending on the thickness of the substrate W to be determined. As an example, in a case where the identification information (ID information) of the accommodation container 9 mounted on the mounting part 20 is registered in advance in the control part 70, the mapping processor 65 may specify the thickness of the accommodated substrate W accommodated in the accommodation container 9 based on the registered identification information, and may make determination by using a value corresponding to the specified thickness.

In the above embodiment, in the mapping process, a determination is made as to whether or not the accommodated substrate W is in the cross abnormality state, and then a determination is made as to whether or not the accommodated substrate W is in the double abnormality state. However, this order may be reversed. That is, the determination may be made as to whether or not the accommodated substrate W is in the double abnormality state, and then the determination may be made as to whether or not the accommodated substrate W is in the cross abnormality state. Alternatively, a determination as to whether or not the accommodated substrate W is in the double abnormality state and the determination as to whether or not the accommodated substrate W is in the cross abnormality state may be made in parallel.

In the above embodiment, in a case where the mapping processor 65 determines that there is a certain abnormality in the accommodation state of the accommodated substrate W (for example, in a case where the cross abnormality state, the double abnormality state, or the like is detected), the mapping processor 65 may notify the control part 70 of this fact, and the control part 70, upon receiving the notification, may perform an appropriate process (for example, a process of sending a stop signal to the door part drive mechanism 50, sending a prohibition signal to prevent the transfer robot 82 from accessing the accommodation container 9, or sounding an alarm, etc.).

In the above embodiment, a sensor may be provided to detect a protruding accommodated substrate W at a position where the substrate W interferes with each of the mapping sensors 61a and 61b. In this case, when the sensor detects the protruding accommodated substrate W, the control part 70 may send a stop signal to the door part drive mechanism 50 to stop the door part 40 from being lowered. Furthermore, a movement command signal may be sent to the local drive mechanism 63 to move each of the mapping sensors 61a and 61b from the detection position MI to the retracted position M2.

In the above-described embodiment, the shape of the substrate W accommodated in the accommodation container 9 is not limited to the rectangular shape and may be, for example, a circular shape. The substrate W may be, for example, a wafer (e.g., a semiconductor wafer), a wafer held on a tape frame (tape frame wafer), an edge ring, a reticle, a liquid crystal transfer object, a copper laminate, a package substrate, a printed circuit board, a culture plate, a culture container, a dish, a Petri dish, or the like. The accommodation container 9 may not be a sealed type, but may also be an open type. The accommodation container 9 may not be a FOUP, but may be, for example, a FOSB, a cassette, or the like. The load port 1 may be used in various fields such as semiconductor manufacturing processes, liquid crystal manufacturing processes, cell culture, or the like. The load port 1 may not be mounted on the EFEM 100.

Other configurations may also be modified in various ways without departing from the spirit of the present disclosure.

### INDUSTRIAL USE OF THE PRESENT INVENTION

The present disclosure can be used as a mapping device and a mapping method capable of determining an accommodation state of a substrate with sufficient accuracy.

### EXPLANATION OF REFERENCE NUMERALS

100: EFEM, 1: load port, 10: base part, 20: mounting part, 30: mounting part drive mechanism, 40: door part, 50: door part drive mechanism, 60: mapping part, 61a: first mapping sensor, 61b: second mapping sensor, 62a: first off-delay timer, 62b: second off-delay timer, 63: local drive mechanism, 64: sensor drive mechanism, 65: mapping processor, 70: control part, Qa: first output signal, Qb: second output signal

1-5. (canceled)

6. A mapping device, comprising:
a first mapping sensor arranged on one side of an end surface of a rectangular substrate accommodated in an accommodation container in an extension direction of the end surface and configured to move in an arrangement direction of the substrate and output an on signal upon detecting the end surface at a first detection point;
a second mapping sensor arranged on the other side of the end surface in the extension direction of the end surface and configured to move in the arrangement direction of the substrate and output an on signal upon detecting the end surface at a second detection point on a downstream side of the first detection point in a direction of the movement of the second mapping sensor; and
a mapping processor configured to determine an accommodation state of the substrate based on a first input signal input from the first mapping sensor and based on a second input signal input from the second mapping sensor via an off-delay timer configured to delay an off signal.

7. The mapping device of claim 6, wherein the mapping processor determines that the substrate is not supported normally when the second input signal is the off signal at both of rising and falling times of the first input signal.

8. The mapping device of claim 6, wherein the first input signal is a signal input from the first mapping sensor to the mapping processor via an off-delay timer configured to delay an off signal, and
wherein a delay time set for the off signal output from the first mapping sensor is shorter than a delay time set for the off signal output from the second mapping sensor.

9. The mapping device of claim 7, wherein the first input signal is a signal input from the first mapping sensor to the mapping processor via an off-delay timer configured to delay an off signal, and
wherein a delay time set for the off signal output from the first mapping sensor is shorter than a delay time set for the off signal output from the second mapping sensor.

10. The mapping device of claim 6, wherein an optical axis of the second mapping sensor is inclined in the direction of the movement of the second mapping sensor with respect to an optical axis of the first mapping sensor.

11. The mapping device of claim 7, wherein an optical axis of the second mapping sensor is inclined in the direction of the movement of the second mapping sensor with respect to an optical axis of the first mapping sensor.

12. A mapping method, comprising:
a detection step of causing a first mapping sensor, which is arranged on one side of an end surface of a rectangular substrate accommodated in an accommodation container in an extension direction of the end surface and configured to output an on signal upon detecting the end surface at a first detection point and a second mapping sensor, which is arranged on the other side of the end surface in the extension direction and configured to output an on signal upon detecting the end surface at a second detection point, to move in an arrangement direction of the substrate and detect the end surface; and
a mapping processing step of determining an accommodation state of the substrate based on a first input signal input from the first mapping sensor and a second input signal input from the second mapping sensor,
wherein the second detection point is located on a downstream side of the first detection point in a direction of the movement of the second mapping sensor, and
wherein the second input signal is a signal input from the second mapping sensor via an off-delay timer configured to delay an off signal.
